(19) United States
(12) Patent Application Publication
(10) Pub. No.: US 2025/0072011 A1
(43) Pub. Date: Feb. 27, 2025

(54) MEMORY DEVICE AND METHOD OF MANUFACTURING THE SAME

(71) Applicant: SK hynix Inc., Icheon-si Gyeonggi-do (KR)

(72) Inventors: Jung Shik JANG, Icheon-si Gyeonggi-do (KR); Seok Min CHOI, Icheon-si Gyeonggi-do (KR); Rho Gyu KWAK, Icheon-si Gyeonggi-do (KR); Won Geun CHOI, Icheon-si Gyeonggi-do (KR); In Su PARK, Icheon-si Gyeonggi-do (KR)

(73) Assignee: SK hynix Inc., Icheon-si Gyeonggi-do (KR)

(21) Appl. No.: 18/584,426

(22) Filed: Feb. 22, 2024

(30) Foreign Application Priority Data
Aug. 24, 2023 (KR) 10-2023-0111312

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/14511

(57) ABSTRACT

A memory device includes a first peripheral circuit having first page buffers is functionally divided into a cell region and a connection region. A first memory cell array positioned on the first peripheral circuit includes first bit lines that are electrically connected to the first page buffers. A second memory cell array positioned on the first memory cell array includes second bit lines, which are electrically connected to the first bit lines, respectively. The first peripheral circuit is able to make use of both memory arrays using connections between the two memory arrays.

### CROSS-REFERENCE TO RELATED APPLICATION

The present application claims priority under 35 U.S.C. § 119(a) to Korean patent application number 10-2023-0111312 filed on Aug. 24, 2023, in the Korean Intellectual Property Office, the entire disclosure of which is incorporated by reference herein.

### BACKGROUND

### 1. Technical Field

The present disclosure relates to a memory device and a method of manufacturing the same, and more particularly, to a memory device manufactured by a wafer bonding technique and a method of manufacturing the same.

### 2. Related Art

A memory device may include a memory cell array in which data is stored and a peripheral circuit configured to perform a program, read, or erase operation of the memory cell array.

A memory cell array of such a memory device may include a plurality of memory blocks. Each memory block of the plurality of memory blocks may include a plurality of memory cells, which are stacked in a vertical direction above a substrate that supports the memory cell array.

Because structures manufactured on different substrates need to physically contact each other, the strength of a bond between different substrates made of different materials, may decrease or the electrical resistance of a connection between the two substrates may increase where different-material.

### SUMMARY

An embodiment of the present disclosure provides a memory device comprising multiple devices that ae stacked on top of each other and a method of manufacturing such a device with an increased bond strength and a reduced interconnection resistance between structures uses bond pads at an interface where different structures are in contact with each other.

According to an embodiment of the present disclosure, a memory device includes a first peripheral circuit including first page buffers and at least two memory cell arrays. The first peripheral circuit and the memory cell arrays are functionally divided or segregated into a cell region and a connection region.

A first memory cell array is located on, i.e., positioned on the first peripheral circuit. First bit lines electrically connect the first page buffers and a second memory cell array positioned on the first memory cell array and second bit lines electrically connected to the first bit lines.

According to an embodiment of the present disclosure, a method of manufacturing a memory device includes: forming a peripheral circuit on a first substrate; forming a first memory cell array including a first stack on a second substrate; forming first cell plugs passing through the first stack, forming first bit lines on the first cell plugs; forming a second memory cell array including a second stack on a third substrate; forming second cell plugs passing through the second stack; forming second bit lines on the second cell plugs, contacting the first memory cell array on the second memory cell array; exposing a portion of the first cell plugs by removing the second substrate positioned on the first memory cell array adjacent to the second memory cell array; forming a first source line including source bonding pads spaced apart from each other on the first cell plugs exposed in the first memory cell array, contacting the first memory cell array including the source bonding pads on the peripheral circuit; exposing a portion of the second cell plugs by removing the third substrate positioned on the second memory cell array, and forming a second source line on the second cell plugs exposed in the second memory cell array.

According to an embodiment of the present disclosure, a memory device includes a first peripheral circuit including first page buffers. The first peripheral circuit is functionally divided or functionally segregated into a cell region and a connection region. A first memory cell array includes first bit lines electrically connected to the first page buffers in the cell region of the peripheral circuit is mounted above the first peripheral circuit A second memory cell array positioned on the first memory cell array includes second bit lines within the cell region of the second memory cell array.

In an alternate embodiment, a second peripheral circuit positioned on the second memory cell array includes second page buffers electrically connected to second bit lines. The first memory cell array includes a first source line positioned at an upper end of the first memory cell array, and first source bonding pads included in the first source line and exposed through an upper surface of the first source line, and the second memory cell array includes a second source line positioned on the first memory cell array, and second source bonding pads included in the second source line and respectively contact the first source bonding pads through a lower surface of the second source line.

According to an embodiment of the present disclosure, a method of manufacturing a memory device includes forming a first peripheral circuit including first contact bonding pads on a first substrate, forming a first memory cell array including second contact bonding pads on a second substrate, turning the first memory cell array so that the second substrate is positioned at an upper portion and the second contact bonding pads are positioned at a lower portion, and contacting the second contact bonding pads of the turned first memory cell array and the first peripheral circuit, removing the second substrate on the first memory cell array and forming a first source line on the first memory cell array, forming first source bonding pads having an exposed upper surface and spaced apart from each other, within the first source line, forming a second peripheral circuit including third contact bonding pads on a third substrate, forming a second memory cell array including fourth contact bonding pads on a fourth substrate, turning the second memory cell array so that the fourth substrate is positioned at an upper portion and the fourth contact bonding pads are positioned at a lower portion, and contacting the fourth contact bonding pads of the turned second memory cell array and the second peripheral circuit, removing the fourth substrate on the second memory cell array and forming a second source line on the second memory cell array, forming second source bonding pads having an exposed upper surface and spaced apart from each other, in the second source line, and contacting the first source bonding pads and the second source bonding pads, respectively.

The present technology may increase bonding strength of an electrical connection interface between different structures in contact with each other.

### BRIEF DESCRIPTION OF THE DRAWINGS

FIG. 1 is a diagram illustrating a memory device.

FIG. 2 is a diagram illustrating a memory cell array.

FIG. 3 is a diagram illustrating a memory block.

FIG. 4 is a perspective view illustrating a memory device according to a first embodiment of the present disclosure.

FIG. 5 is a cross-sectional view illustrating the memory device according to the first embodiment of the present disclosure, showing a peripheral circuit formed on its own substrate, which is bonded to two stacked memory devices, formed on their own substrates and which are bonded to each other.

FIGS. 6A to 6D are diagrams illustrating various layouts of a source bonding pad.

FIG. 7 is a diagram illustrating a layout of the memory device according to the first embodiment of the present disclosure.

FIGS. 8A to 8J are diagrams illustrating a method of manufacturing the memory device according to the first embodiment of the present disclosure.

FIG. 9 is a cross-sectional view illustrating a memory device according to a second embodiment of the present disclosure.

FIG. 10 is a diagram illustrating a layout of the memory device according to the second embodiment of the present disclosure.

FIG. 11 is a perspective view illustrating a memory device according to a third embodiment of the present disclosure.

FIGS. 12A to 12C are cross-sectional views illustrating the memory device according to the third embodiment of the present disclosure.

FIG. 13 is a diagram illustrating a layout of the memory device according to the third embodiment of the present disclosure.

FIGS. 14A to 14K are diagrams illustrating a method of manufacturing the memory device according to the third embodiment of the present disclosure.

FIG. 15 is a diagram illustrating a memory card system to which a memory device of the present disclosure is applied.

FIG. 16 is a diagram illustrating a solid state drive (SSD) system to which a memory device of the present disclosure is applied.

### DETAILED DESCRIPTION

Specific structural or functional descriptions disclosed below describe a preferred embodiment of the claimed subject matter. No disclosed embodiment should be construed as limiting the scope of any claim.

Hereinafter, terms such as first and second may be used to describe various components, but the components are not limited by such terms. The terms first, second and the like are used to distinguish one component from another component and do not denote or imply anything else.

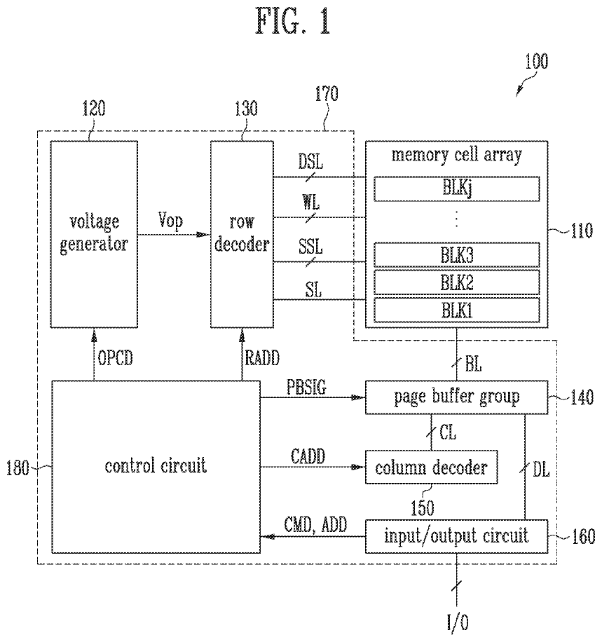

FIG. 1 is a diagram illustrating a memory device 100.

Referring to FIG. 1, the memory device 100 may include a memory cell array 110 and a peripheral circuit 170.

The memory cell array 110 may include first to j-th memory blocks BLK1 to BLKj. Each of the first to j-th memory blocks BLK1 to BLKj may include memory cells, each of which is capable of storing data. Drain select lines DSL, word lines WL, source select lines SSL, and a source line SL may be connected between a row decoder 130 and each of the first to j-th memory blocks BLK1 to BLKj of the memory cell array 110. Bit lines BL may be connected between a page buffer group 130 and the first to j-th memory blocks BLK1 to BLKj of the same memory cell array 110.

The first to j-th memory blocks BLK1 to BLKj may be formed as a two-dimensional structure or a three-dimensional structure. Memory blocks having a two-dimensional structure may include memory cells formed by at least two layers of semiconductor materials, which are formed on top of each other, both layers being on top of and parallel to a substrate. The memory blocks having a three-dimensional structure may include memory cells formed of multiple, separate two-dimensional memory cell structures, which are vertically stacked on top of each other, the several two-dimensional memory cell structures being stacked on top of each other on a substrate. Memory blocks formed in a three-dimensional structure are disclosed in the present embodiment.

The memory cells may store 1 bit, or 2 bits or more of data according to a program method. For example, a method in which 1 bit of data is stored in one memory cell is referred to as a single level cell method. A method in which 2 bits of data is stored in one memory cell is referred to as a multi-level cell method. A method in which 3 bits of data is stored in one memory cell is referred to as a triple level cell method, and a method in which 4 bits of data is stored in one memory cell is referred to as a quad level cell method. In addition to this, five bits or more of data may be stored in one memory cell.

The peripheral circuit 170, which includes circuits and structures enclosed within a dashed or broken line, may be configured to perform a program operation, which is an operation for storing data in the memory cell array 110. The peripheral circuit 170 also may be configured to perform a read operation, which is an operation for outputting data stored in the memory cell array 110 and an erase operation, which is an operation for erasing data stored in the memory cell array 110. As shown in FIG. 1 the peripheral circuit 170 may include a voltage generator 120, a row decoder 130, a page buffer group 140, a column decoder 150, an input/output circuit 160, and a control circuit 180, all of which are enclosed within a dashed or broken line.

The voltage generator 120 may generate various operation voltages Vop used for the program operation, the read operation, or the erase operation in response to an operation code OPCD. The voltage generator 120 may thus be configured to generate program voltages, turn-on voltages, turn-off voltages, negative voltages, pre-charge voltages, verify voltages, read voltages, pass voltages, or erase voltages in response to the operation code OPCD. The various different operation voltages Vop generated by the voltage generator 120 may be applied to the drain select lines DSL, the word lines WL, the source select lines SSL, and the source line SL of memory block selected through the row decoder 130.

The program voltages may be voltages applied to a selected word line among the word lines WL during the program operation, and may be used to increase a threshold voltage of memory cells connected to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or the source select transistors. For example, the turn-off voltage may be set to 0V. The precharge voltages may be a voltage higher than 0V, and may be applied to bit lines during the read operation. The verify voltages may be used during a verify operation for determining whether a threshold voltage of selected memory cells is increased to a target level. The verify voltages may be set to various levels according to the target level, and may be applied to the selected word line.

The read voltages may be applied to the selected word line during the read operation of the selected memory cells. For example, the read voltages may be set to various levels according to a program method of the selected memory cells. The pass voltages may be voltages applied to unselected word lines among the word lines WL during the program or read operation, and may be used to turn on memory cells connected to the unselected word lines.

The erase voltages may be used during the erase operation for erasing memory cells included in the selected memory block, and may be applied to the source line SL.

The row decoder 130 may be configured to transmit the operation voltages Vop to the drain select lines DSL, the word lines WL, the source select lines SSL, and the source line SL connected to the selected memory block according to a row address RADD. For example, the row decoder 130 may be connected to the voltage generator 120 through global lines, and may be connected to the first to j-th memory blocks BLK1 to BLKj through the drain select lines DSL, the word lines WL, the source select lines SSL, and the source line SL.

The page buffer group 140 may include page buffers PB1 to PBn (not shown) connected to the first to j-th memory blocks BLK1 to BLKj. Each of the page buffers (not shown) may be connected to the first to j-th memory blocks BLK1 to BLKj through corresponding bit lines BL. During the read operation, the page buffers (not shown) may sense a current or a voltage of a bit line, which varies according to threshold voltages of the selected memory cell, The page buffers may temporarily store the sensed data in response to page buffer control signals PBSIG.

The column decoder 150 may be configured so that data is transmitted between the page buffer group 140 and the input/output circuit 160 in response to a column address CADD. For example, the column decoder 150 may be connected to the page buffer group 140 through column lines CL and may transmit enable signals through the column lines CL. The page buffers (not shown) included in the page buffer group 140 may receive or output the data through data lines DL in response to the enable signals.

The input/output circuit 160 may be configured to receive or output, one or more of: a command CMD, an address ADD, or data, through input/output lines I/O. For example, the input/output circuit 160 may transmit to the control circuit 180, a command CMD and an address ADD, which are received by the input/output circuit 160 from an external controller through the input/output lines I/O. The input/output circuit 160 may also transmit to the page buffer group 140 through the input/output lines I/O, data that the page buffer group 140 receives from the external controller. Alternatively, the input/output circuit 160 may output data received from the page buffer group 140 to the external controller through the same input/output lines I/O.

The control circuit 180 may output an operation code OPCD, a row address RADD, a page buffer control signal PBSIG, and a column address CADD, in response to a command CMD and an address ADD received by the control circuit 180 from an external controller, not shown, on the input/output lines I/O. For example, when the command CMD input to the control circuit 180 is a command corresponding to the program operation, the control circuit 180 may control devices included in the peripheral circuit 170 to cause them to perform a program operation on a memory block selected by an address ADD received from the external controller. Similarly, when the command CMD input to the control circuit 180 is a command corresponding to the read operation, the control circuit 180 may control the devices included in the peripheral circuit 170 to cause them to perform the read operation of the memory block selected by an address that accompanies a read command and output the data that is read from the memory cell identified by, or corresponding to the address received with the read command. When the command CMD input to the control circuit 180 is for the erase operation, the control circuit 180 may control the devices included in the peripheral circuit 170 to perform the erase operation on a memory block selected by or corresponding to one or more addresses or an address range, received by the control circuit 180 along with an erase operation command.

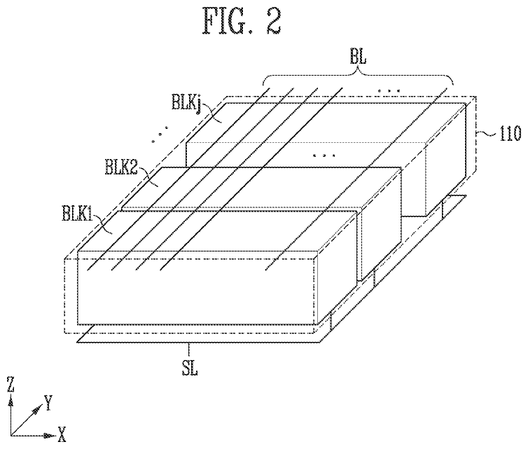

FIG. 2 is a diagram illustrating a portion of a memory cell array.

Referring to FIG. 2, the memory cell array 110 may include the first to j-th memory blocks BLK1 to BLKj. Each of the first to j-th memory blocks BLK1 to BLKj may include a plurality of memory cells (not visible in FIG. 2) which are vertically stacked on top of each other as described below to form a three-dimensional memory cell array structure 110. The first to j-th memory blocks BLK1 to BLKj may be arranged to be spaced apart from each other along a Y direction and may extend along an X direction.

Conceptually but not actually, the first to j-th memory blocks BLK1 to BLKj may be located or positioned between two, vertically-separated parallel X-Y planes, in which the source line SL and the bit lines BL are located. The source line SL may be commonly connected to, i.e., connected to each of, the first to j-th memory blocks BLK1 to BLKj. Each bit line BL may be commonly connected to memory cells of each of the first to j-th memory blocks BLK1 to BLKj. The bit lines BL may extend in the Y direction and may be laterally spaced apart from each other along the X direction such that the bit lines BL are electrically isolated from each other as well laterally and spatially separated from each other.

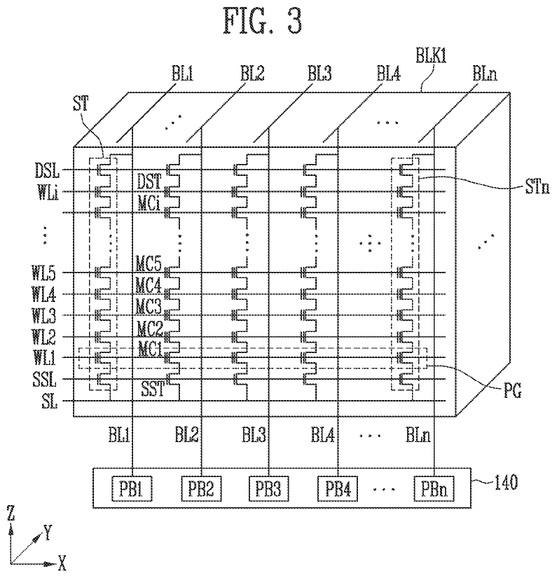

FIG. 3 is a diagram illustrating a memory block, BLK1, and an exemplar of memory blocks BLK1-BLKj depicted in FIG. 1.

Referring to FIG. 3, the first memory block BLK1 may include a plurality of cell strings ST-STn. The cell strings ST-STn are parallel to each other in an X-Z plane and a Y-Z plane Each cell string ST-STn, is connected between the source line SL and a corresponding one of first to n-th bit lines BL1 to BLn.

The cell strings ST-STn may be commonly connected to the source line SL. Some of the cell strings ST may be connected to the first to n-th bit lines BL1 to BLn, respectively, and some other cell strings ST may be connected to the same bit line among the first to n-th bit lines BL1 to BLn. For example, the cell strings ST arranged in the X direction may be respectively connected to the first to n-th bit lines BL1 to BLn. Cell strings arranged in the Y direction may be connected to the same bit line.

The first to n-th bit lines BL1 to BLn may be electrically connected to first to n-th page buffers PB1 to PBn included in the page buffer group 140, respectively. For example, the first bit line BL1 may be electrically connected to the first page buffer PB1, and the n-th bit line BLn may be electrically connected to the n-th page buffer PBn.

Each of the plurality of cell strings ST may include a source select transistor SST, first to i-th memory cells MC1 to MCi, and a drain select transistor DST. The cell string ST connected to the first bit line BL1 among the plurality of cell strings ST is described as an example as follows.

The source select transistor SST may be connected between the source line SL and the first memory cell MC1, and the drain select transistor DST may be connected between the i-th memory cell MCi and the first bit line BL1. The first to i-th memory cells MC1 to MCi may be connected between the source select transistor SST and the drain select transistor DST. The number of source select transistors SST and drain select transistors DST is not limited to the number shown in FIG. 3. In addition to the first to i-th memory cells MC1 to MCi, dummy cells may be further connected between the source select transistor SST and the drain select transistor DST. The first to i-th memory cells MC1 to MCi may store user data or normal data, and the dummy cells may store dummy data.

Gates of the source select transistors SST, which are located at the bottom of each cell string ST, one of which is included in each of the different cell strings ST, may be connected to the same source select line SSL. Gates of the first to i-th memory cells MC1 to MCi included in different cell strings ST may be connected to corresponding first to i-th word lines WL1 to WLi. Gates of the drain select transistors DST, each of which is located at the top of each cell string ST and included in each of the different cell strings ST, may be connected to the same drain select line DSL. Memory cells, MC that comprise a cell string ST in the X direction and which are connected to the same word line WL comprise a memory page PG. In the memory device 100, a program operation or a read operation of a selected memory block may be performed in a page PG unit.

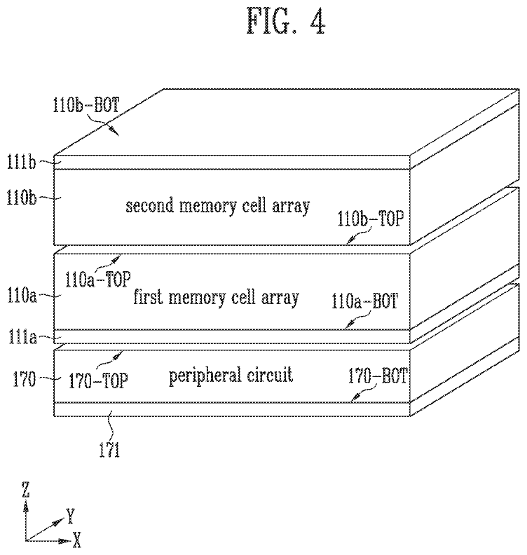

FIG. 4 is a perspective view illustrating a memory device according to a first embodiment of the present disclosure.

Referring to FIG. 4, the memory device 400 may include a first memory cell array 110a and a second memory cell array 110b stacked on top of each other in the Z direction. The two stacked memory cell arrays, 110a and 110b, are stacked on top of the peripheral circuit 170, also in the Z direction.

The peripheral circuit 170, the first memory cell array 110a, and the second memory cell array 110b may be formed independently of each other on different substrates. Those two different memory cell array substrates may then be additionally processed to make contact with and bonded to each other. The first memory cell array 110a may then be bonded to the peripheral circuit 170, which effectively bonds both memory cell arrays to the peripheral circuit 170.

The peripheral circuit 170 may be formed on a first substrate 171, the first memory cell array 110a may be formed on a second substrate 111a, and the second memory cell array 110b may be formed on a third substrate 111b.

The first memory cell array 110a, the second memory cell array 110b and the peripheral circuit 170 each have a top surface and an opposing bottom surface. The first memory cell array 110a top surface is identified in FIG. 4 as 110a-TOP; its bottom surface is identified as 110a-BOT. The second memory cell array 110b top surface is identified as 110b-TOP; its bottom surface as 110b-BOT. The top surface of the peripheral circuit 170 is identified as 170-TOP; the bottom surface by 170-BOT.

When the first memory cell array 110a is formed on the second substrate 111a and the second memory cell array 110b is formed on the third substrate 111b, the first memory cell array 110a may physically touch, i.e., be in physical contact with, the second memory cell array 110b The second substrate layer 111a may thereafter be removed from the bottom surface of the first memory cell array 110a. When the second substrate layer 112a of the first memory cell array 110a is removed from the first memory array 110a, a source line and source bonding pads (not visible in FIG. 4) may be formed on the lower or bottom surface 110a-BOT of the first memory cell array 110a from which the second substrate is removed. The first memory cell array 110a including the formed source bonding pads may then contact with and be electrically connected to bonding pads or equivalent electrical connection structures on the “upper” surface 170-TOP of the peripheral circuit 170. The first memory cell array 110a may thus be stacked on and electrically connected to electrical components of the peripheral circuit 170 by electrical connections that extend through both structures 170 and 110a.

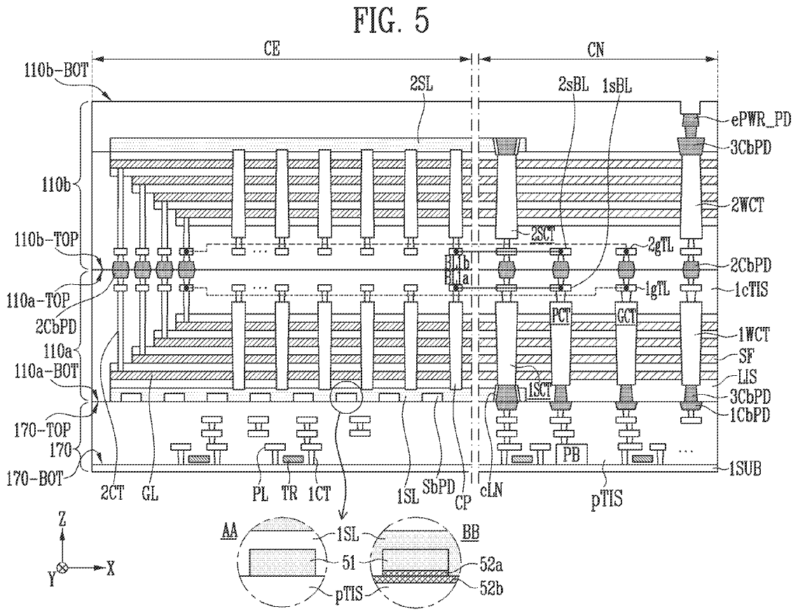

As shown in FIG. 5, the second memory cell array 110b may be inverted and then stacked on and electrically connected to components of the first memory cell array 110a. If the third substrate on the bottom of the second memory cell array 110b is removed, a source line may be formed on the exposed bottom surface 110b-BOT of the second memory cell array 110b from which the third substrate is removed.

Because the top surfaces of the first and second memory cell arrays 110a and 110b face each other the two memory cell arrays are stacked on top of each other by joining the two top surfaces to each other. Their stacked combination is then stacked on top of the peripheral circuit 170. Electrical contacts and lines may be formed and appropriately located inside the peripheral circuit 170 but also on the surface of the peripheral circuit 170 that mates with, i.e., makes contact with and is bonded to, one or both of the memory cell arrays 110a and 110b. Similarly, electrical contacts and lines may be formed in the memory cell arrays 110a and 110b and on mating external surfaces of the first and second memory cell arrays 110a and 110b so that the stacked peripheral circuit 170 and the stacked first and second memory cell arrays 110a and 110b are electrically connected to each other. The electrical contacts and lines formed in, as well as on, an external surface of the peripheral circuit 170 and the memory cell arrays 110a, 110b, thus enable the peripheral circuit 170 to be independently connected to both memory cell arrays 110a and 110b, which may also be connected to each other. The electrically connected peripheral circuit 170 and the first and second memory cell arrays 110a and 110b are described hereinafter with reference to FIG. 5.

FIG. 5 is a cross-sectional view illustrating the memory device according to the first embodiment of the present disclosure.

As shown in FIG. 5, the second or top memory layer 110b is “flipped over” vis-à-vis the first or bottom memory layer 110a. The top surfaces of the two memory layers 110a and 110b are thus considered to be “facing” each other. For brevity purposes, the memory array layers 110a and 110b are referred to hereinafter simply as memory arrays, i.e., memory array 110a and memory array 110b.

Referring now to the peripheral circuit 170 of FIG. 5, a first substrate 1SUB, which may be silicon, comprises one or more transistors TR, first contacts 1CT, and peripheral lines PL. The transistors TR may be PMOS or NMOS transistors. The first contacts 1CT, which are made of a conductive material, may be located and formed in the first substrate 1SUB to electrically connect components in the first substrate 1SUB and peripheral lines PL to each other. Other first contacts 1CT may electrically connect the peripheral lines PL to each other. Therefore, the first contacts 1CT and the peripheral lines PL may be formed of a conductive material.

As shown by markings at the top of FIG. 5, the peripheral circuit 170 at the bottom of FIG. 5 may be considered to be functionally, but not physically separated or “divided” into a cell region CE located in the left-hand side of FIG. 5 and a connection region CN located in the right-hand side of FIG. 5. The cell region CE and the connection region CN may be defined as regions laterally adjacent to each other. The cell region CE and the connection region CN are functionally separate regions on the same physical substrate 1SUB. They are not on separate or different physical substrates.

In the cross-section shown in FIG. 5, the cell region CE and the connection region CN are divided from each other at a location along the X direction but may also be divided from each other at a location along the Y direction or an XY direction. A plurality of page buffers, depicted in FIG. 3, including the first page buffer PB1, may be positioned in the cell region CE and connection region CN of the peripheral circuit 170 depicted in FIG. 5. First contact bonding pads 1CbPD may be positioned on the top surface of the peripheral circuit 170 in the cell region CE and in the connection region CN. Only one page buffer PB is depicted in FIG. 5.

In addition to the page buffers PB, the voltage generator 120 of FIG. 1, the row decoder 130 of FIG. 1, the column decoder 150 of FIG. 1, the input/output circuit 160 of FIG. 1, and the control circuit 180 of FIG. 1 may all be included in the cell region CE and the connection region CN of the peripheral circuit 170. Those structure are omitted from FIG. 5 in the interest of illustration clarity.

A peripheral gap fill layer pTIS, which may be an insulating or dielectric material and identified by stippling, may be formed between and around transistors TR, the first contacts 1CT, the peripheral lines PL, the plurality of page buffers including the first page buffer PB1, and the first contact bonding pads 1CbPD.

The first contact bonding pads 1CbPD, which in FIG. 5 are located at the top 170-TOP of the peripheral circuit 170, may be in direct contact with an upper portion of first contacts 1CT in the peripheral circuit 170 and may be made of a conductive material such as tungsten (W). In the peripheral circuit 170 shown in FIG. 5, which is a vertical cross section, peripheral lines PL positioned in different layers, and which extend into and out of the plane of FIG. 5, may be electrically connected to each other through the first contacts 1CT. In the vertical cross-section of FIG. 5, some peripheral lines PL spaced apart from each other and arranged on the same X-Y plane may be connected to each other.

The first memory cell array 110a, which is stacked on the peripheral circuit 170, may include line insulating layers LIS between each gate line GL, second contact bonding pads 2CbPD, a first source line 1SL, source bonding pads SbPD, gate lines GL, sacrificial layers SF, cell plugs CP, second contacts 2CT, a first source contact 1SCT, a page buffer contact PCT, a gate line contact GCT, a first power contact 1WCT, third contact bonding pads 3CbPD, a first bit line group BL1a, and a first cell interlayer insulating layer 1cTIS.

The first source line 1SL and the source bonding pads SbPD which are in contact with the peripheral circuit 170 may be positioned in the cell region CE of the first memory cell array 110a. Because the first source line 1SL is used as a source line in the first memory cell array 110a, the first source line 1SL may be formed of a conductive layer. For example, the first source line 1SL may be formed of polysilicon. Inside the first source line 1SL, the source bonding pads SbPD contacting the peripheral gap fill layer pTIS of the peripheral circuit 170 may be included. The source bonding pads SbPD may be exposed through a lower surface of the first source line 1SL. A lower surface of the source bonding pads SbPD and the first source line 1SL may be the same plane. Therefore, the first source line 1SL and the source bonding pads SbPD may be in contact with the peripheral circuit 170. For example, in the cell region CE, because the peripheral gap fill layer pTIS is exposed through an upper surface of the peripheral circuit 170, the first source line 1SL and the source bonding pads SbPD exposed through a lower surface of the first memory cell array 110a may be in contact with the peripheral gap fill layer pTIS. Because the peripheral gap fill layer pTIS is formed of an insulator or a dielectric, the strength of the bond between the first source line 1SL, which is a conductive layer, and the peripheral gap fill layer pTIS, may be reduced. Because the source bonding pads SbPD are formed of a dielectric, the strength of the bond between the peripheral gap fill layer pTIS and the source bonding pads SbPD may greater than that with the first source line 1SL.

Referring now to enlarged views AA and BB, which show how and where portions of the source bonding pads SbPD and the peripheral gap fill layer pTIS are in contact each other, the source bonding pads SbPD may be formed as a single layer including a first dielectric layer 51. The peripheral gap fill layer pTIS may also be formed as a single layer of an insulating or dielectric layer. Referring to the enlarged view ‘BB’, each of the source bonding pads SbPD may be formed as multiple layers including the first dielectric layer 51 and a second dielectric layer 52a. The second dielectric layer 52a may be a dielectric material different from that of the first dielectric layer 51. A third dielectric layer 52b may be further formed on an upper surface of the peripheral gap fill layer pTIS. The third dielectric layer 52b may be the same material as the second dielectric layer 52a.

Because the source bonding pads SbPD are included under the first source line 1SL, the bonding strength between the first peripheral circuit 170 and the first memory cell array 110a may be increased in the cell region CE.

The line insulating layers LIS and the gate lines GL may be alternately stacked on the first source line 1SL. The insulating layers LIS and the gate lines GL may be stacked in a step shape. For example, a pair of the line insulating layer LIS and the gate line GL may form one step. The line insulating layers LIS may be an oxide layer, and the gate lines GL may be a conductive layer. For example, the gate lines GL may be formed of at least one of tungsten (W), cobalt (Co), nickel (Ni), molybdenum (Mo), silicon (Si), and poly-silicon (poly-Si), and may be formed of various other conductive layers.

The cell plugs CP, which extend in the Z direction through the line insulating layers LIS and the gate lines GL, may be arranged such that the cell plugs CP are vertically parallel to each other and spaced apart from each other in the X, Y, or XY directions. Among the cell plugs CP, portions surrounded by the gate lines GL may be source select transistors, memory cells, or drain select transistors. A lower portion of the cell plugs CP may be in contact with the first source line 1SL. For example, lower ends or lower surfaces of the cell plugs CP may be in contact with the first source line 1SL.

As shown in FIG. 5, a first bit line group BL1a may be arranged on or at the top of the cell plugs CP. The cell plugs CP may thus be considered to be located vertically between a bit line BL, which is at or near the top of a cell plug CP, and a source line, SL, which is at or near the bottom of a cell plug CP.

The first bit line group BL1a may include bit lines electrically connected to the cell plugs CP. For example, the bit lines BL included in the first bit line group BL1a may be contact with the cell plugs CP through second contacts 2CT. Some lines or some pads positioned on different layers in the first memory cell array 110a may be electrically connected to each other through the second contacts 2CT. For example, the gate lines GL having a step structure may be in contact with the second contact bonding pads 2CbPD through the second contacts 2CT. The second contact bonding pads 2CbPD may be formed of a conductive layer. For example, the second contact bonding pads 2CbPD may be formed of tungsten (W).

The line insulating layers LIS and the sacrificial layers SF alternately stacked on the peripheral circuit 170 may be formed in the connection region CN of the first memory cell array 110a. The third contact bonding pads 3CbPD respectively contacting the first contact bonding pads 1CbPD may be formed in the lowermost line insulating layer LIS. The third contact bonding pads 3CbPD may be formed of a conductive material such as tungsten (W).

The first source contact 1SCT, the page buffer contact PCT, the gate line contact GCT, and the first power contact 1WCT may pass through the line insulating layers LIS and the sacrificial layers SF between the third contact bonding pads 3CbPD and the second contact bonding pads 2CbPD.

The first source contact 1SCT, the page buffer contact PCT, the gate line contact GCT, and the first power contact 1WCT may be formed of a conductive material. The first source contact 1SCT, the page buffer contact PCT, the gate line contact GCT, and the first power contact 1WCT may be electrically connected to the third contact bonding pads 3CbPD and the second contact bonding pads 2CbPD through the second contacts 2CT.

The first source contact 1SCT may be electrically connected to the peripheral circuit 170 and the first source line 1SL through a third contact bonding pad 3CbPD. A side surface of the third contact bonding pad 3CbPD that is in contact with the first source contact 1SCT may be surrounded by a contact liner layer cLN, which may be formed of a conductive material such as titanium Ti or titanium silicide TiSi. Because the contact liner layer cLN and the third contact bonding pad 3CbPD are formed of a conductive layer, the source voltage generated in the peripheral circuit 170 may be transferred to the first source line 1SL through the first contact bonding pad 1CbPD, the third contact bonding pad 3CbPD, and the contact liner layer CLN. The source voltage may be a ground voltage, a positive voltage, or a negative voltage. Because the first source contact 1SCT is in contact with the third contact bonding pad 3CbPD, a voltage applied to the third contact bonding pad 3CbPD may be transmitted to the second contact bonding pad 2CbPD positioned in an upper region of the first memory cell array 110a.

The page buffer contact PCT may be positioned between the third contact bonding pad 3CbPD and the second contact bonding pad 2CbPD. The page buffer contact PCT may be electrically connected to the page buffer PB through the first contact bonding pad 1CbPD and the first contacts 1CT of the peripheral circuit 170. First sub-bit lines 1sBL connected to the first bit line group BL1a may be positioned between the page buffer contact PCT and the second contact bonding pad 2CbPD. For example, the bit lines included in the first bit line group BL1a may be electrically connected to the page buffers PB of the peripheral circuit 170 through the first sub-bit lines 1sBL and the page buffer contacts PCT. The page buffer contacts PCT connected to different bit lines may be connected to different page buffers PB included in the peripheral circuit 170.

The gate line contact GCT may be electrically connected to the gate line GL of the cell region CE through a first gate transmission line 1gTL and the second contact 2CT. For example, a word line voltage generated in the peripheral circuit 170 may be transmitted to a selected gate line GL through the first contact bonding pad 1CbPD, the gate line contact GCT, the first gate transmission line 1gTL, and the second contact 2CT.

The first power contact 1WCT may supply external power applied through the second memory cell array 110b to the peripheral circuit 170 through a second contact bonding pad 2CbPD and a first contact bonding pad 1CbPD.

The second memory cell array 110b, which is inverted or “upside down” relative to the first memory cell array 110a, may be a structure that is symmetrical to remaining configurations except for a portion of the page buffer contact PCT, the gate line contact GCT, the source bonding pads SbPD, and the third contact bonding pads 3CbPD of the first memory cell array 110a.

For example, the second memory cell array 110b may include a structure that is symmetrical to the first memory cell array 110a but inverted relative to an X-Y plane. Therefore, the first cell interlayer insulating layer 1cTIS of the second memory cell array 110b and the first cell interlayer insulating layer 1cTIS of the first memory cell array 110a are vertically adjacent to each other in the Z-direction and in direct, mechanical contact with each other. e As shown in FIG. 5, the second contact bonding pads 2CbPD, which are located at the “top” of the “inverted” or upside-down second memory cell array 110b (i.e., relative to the first memory cell array 110a) and the second contact bonding pads 2CbPD, which are located at the top of the upright first memory cell array 110a are mechanically bonded to each other and electrically bonded to each other. The bonds between the second bonding pads 2CbPD in the first and second memory cell arrays 110a and 110b enable electrical signals to be exchanged between the two memory cell arrays 110a and 110b. Stacking multiple memory array devices on top of each other as shown in FIG. 5 and stacking those stacked memory array devices on a peripheral circuit thus provides a memory array device with a doubled data capacity in the same area or footprint required by a single memory array device.

The second source contact 2SCT included in the second memory cell array 110b may be electrically connected to the first source contact 1SCT of the first memory cell array 110a through corresponding second contact bonding pads 2CbPD in the memory cell arrays 110a and 110b. Therefore, the source voltage applied to the first source contact 1SCT may be transferred to a second source line 2SL of the second memory cell array 110b through the second source contact 2SCT.

The bit lines included in the second bit line group BL1b included in the second memory cell array 110b may be electrically connected to the page buffers PB of the peripheral circuit 170 through second sub-bit lines 2sBL, the second contact bonding pads 2CbPD, the page buffer contacts PCT, the third contact bonding pads 3CbPD, and the first contact bonding pads 1CbPD. Therefore, the page buffers PB of the peripheral circuit 170 may be simultaneously connected to the first bit line group BL1a of the first memory cell array 110a and the second bit line group BL1b of the second memory cell array 110b.

The gate line GL of the second memory cell array 110b may be electrically connected to the gate line contact GCT through the second contact 2CT, the second contact bonding pad 2CbPD, and the second gate transmission line 29TL. Therefore, the word line voltage generated in the peripheral circuit 170 may be transmitted to the selected gate lines GL of the first memory cell array 110a and the second memory cell array 110b through the gate line contact GCT, the first gate transmission line 1gTL, and the second gate transmission line 2gTL.

An external power pad ePWR_PD at the uppermost layer of the stack of layers 170, 110a and 110b, may be formed on the “bottom” 110b-BOT of the second memory cell array 110b, preferably before the second memory cell array 110b is inverted and bonded to the first memory cell array 110a so that the external power pad ePWR_PD is readily accessible after the second memory cell array 110b is inverted and bonded to the first memory cell array 110a. The external power pad ePWR_PD may be electrically connected to the first power contact 1WCT of the first memory cell array 110a through the third contact bonding pad 3CbPD, the second power contact 2WCT, and the second contact bonding pads 2CbPD of the second memory cell array 110b.

As used herein, a horizontal cross-section, which is also known as parallel cross-section, is a two-dimensional shape formed or made when a geometric plane cuts a solid shape in a horizontal direction such that the cutting geometric plane creates a cross-sectional shape that is parallel to the base.

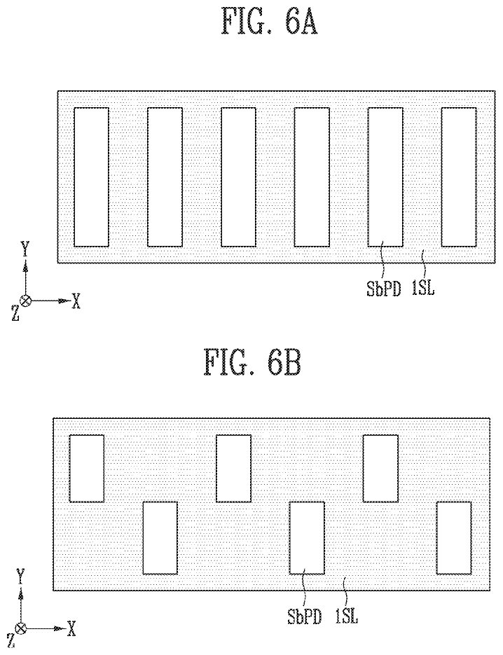

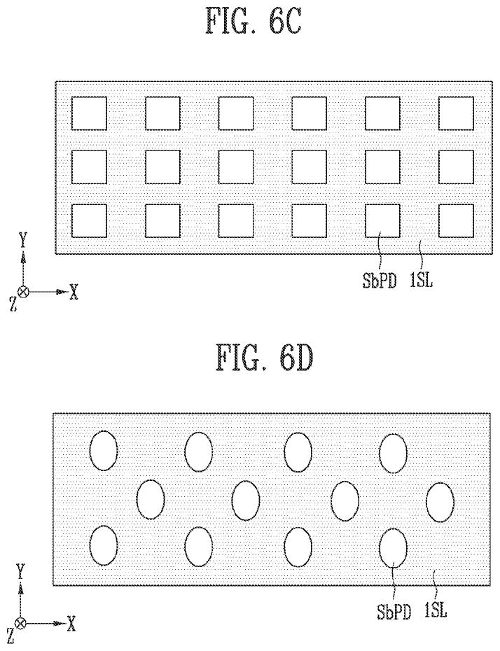

FIGS. 6A to 6D are diagrams illustrating various horizontal cross-sectional shapes/layouts of a source bonding pad.

Referring to FIGS. 5 and 6A, the first source line 1SL of the first memory cell array 110a may include source bonding pads SbPD contacting the peripheral gap fill layer pTIS of the peripheral circuit 170. Because the source bonding pads SbPD are included in the first source line 1SL, a size increase due to the source bonding pads SbPD does not occur. The source bonding pads SbPD may be formed to be spaced apart from each other within the first source line 1 SL. As shown in FIG. 6A, the source bonding pads SbPD may be formed to have a horizontal cross-sectional shape that is substantially rectangular the long axis of which extends in the Y direction; the short axis extends in the X direction, and may be spaced separated from adjacent source bonding pads SbPD in the X direction.

Referring to FIGS. 5 and 6B, each of the source bonding pads SbPD may be formed to have a substantially rectangular shape, best seen in FIG. 6B or a substantially square shape, best seen in FIG. 6C. The source bonding pads SbPD may be arranged to be spaced apart from each other and staggered in a zigzag direction along the X or Y direction.

Referring to FIGS. 5 and 6C, each of the source bonding pads SbPD may be formed to have a substantially square shape. The source bonding pads SbPD may be arranged in a matrix form spaced apart from each other in the X or Y directions.

Referring to FIGS. 5 and 6D, each of the source bonding pads SbPD may be formed in a circular or oval shape. The source bonding pads SbPD may be arranged to be spaced apart from each other in a staggered or zigzag direction in the X or Y directions.

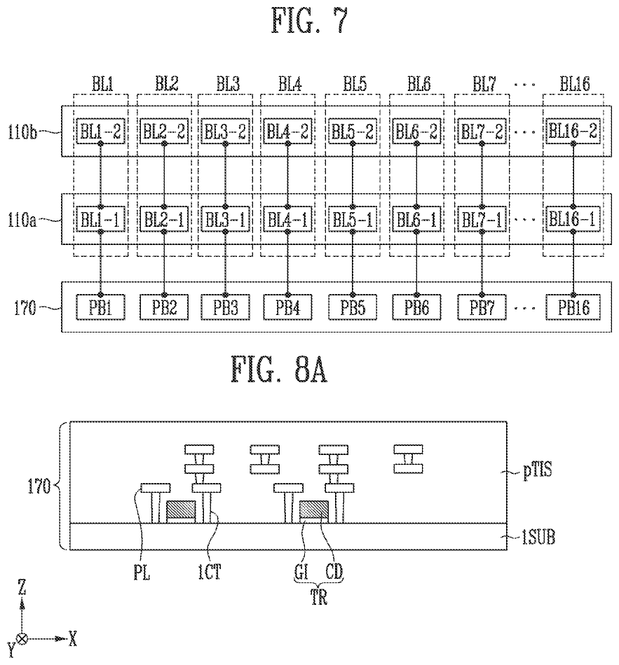

FIG. 7 is a vertical cross-sectional diagram illustrating a layout of the memory device according to the first embodiment of the present disclosure.

Referring to FIGS. 5 and 7, a memory device including first to sixteenth page buffers PB1 to PB16 in the peripheral circuit 170 is shown as an example, but the number of page buffers may vary according to the memory device.

The first to sixteenth page buffers PB1 to PB16 included in the peripheral circuit 170 may be connected to bit lines BL1-1 to BL16-1 included in the first memory cell array 110a and bit lines BL1-2 to BL16-2 included in the second memory cell array 110b, respectively. For example, the first page buffer PB1 may be commonly connected to the (1-1)-th bit line BL1-1 of the first memory cell array 110a and the (1-2)-th bit line BL1-2 of the second memory cell array 110b. The second page buffer PB2 may be commonly connected to the (2-1)-th bit line BL2-1 of the first memory cell array 110a and the (2-2)-th bit line BL2-2 of the second memory cell array 110b. In such a method, the sixteenth page buffer PB16 may be commonly connected to the (16-1)-th bit line BL16-1 of the first memory cell array 110a and the (16-2)-th bit line BL16-2 of the second memory cell array 110b. That is, the first bit line BL1 connected to the first page buffer PB1 may be divided into the (1-1)-th bit line BL1-1 included in the first memory cell array 110a and the (1-2)-th bit line BL1-2 included in the second memory cell array 110b, and the (1-1)-th bit line BL1-1 and the (1-2)-th bit line BL1-2 may be electrically connected to each other. In such a method, the sixteenth bit line BL16 connected to the sixteenth page buffer PB16 may be divided into the (16-1)-th bit line BL16-1 included in the first memory cell array 110a and the (16-2)-th bit line BL16-2 included in the second memory cell array 110b, and the (16-1)-th bit line BL16-1 and the (16-2)-th bit line BL16-2 may be electrically connected to each other.

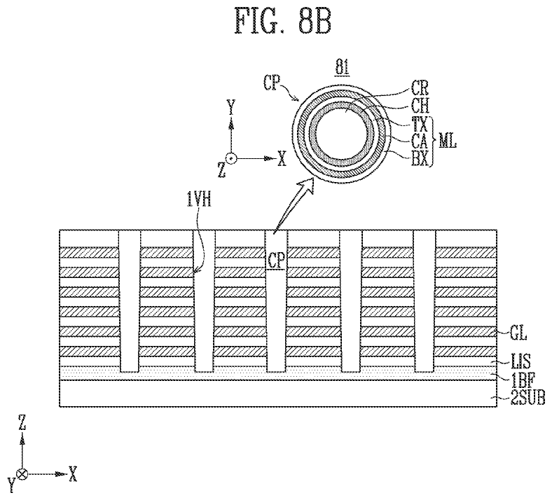

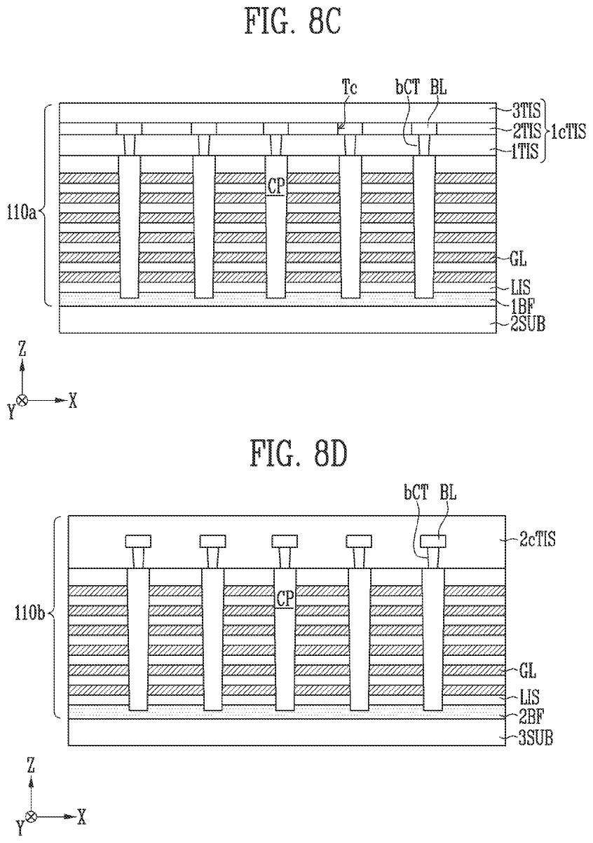

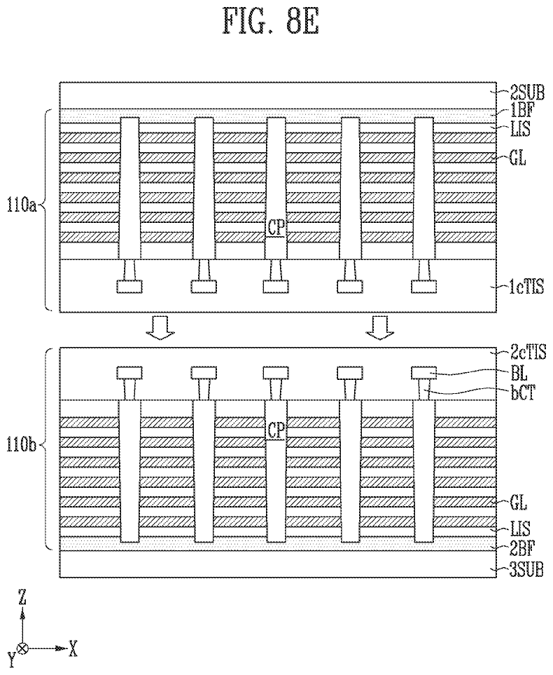

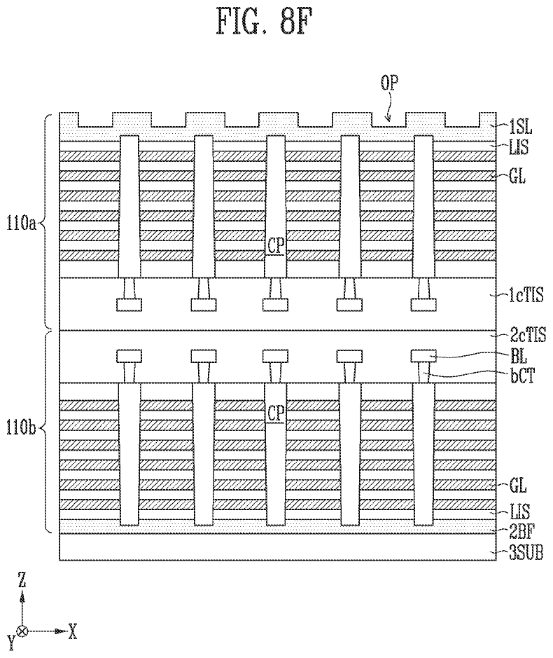

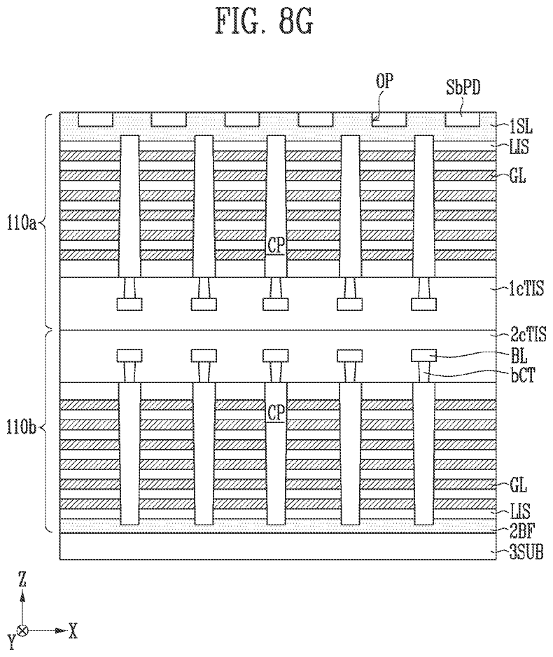

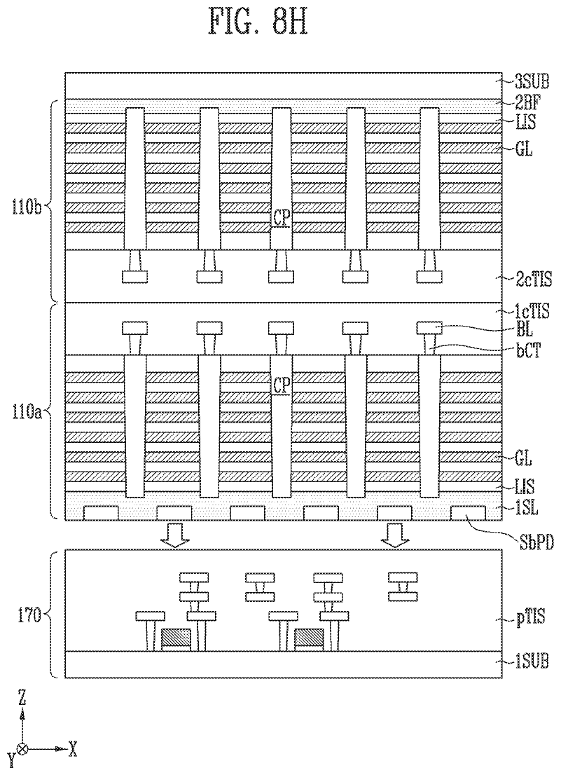

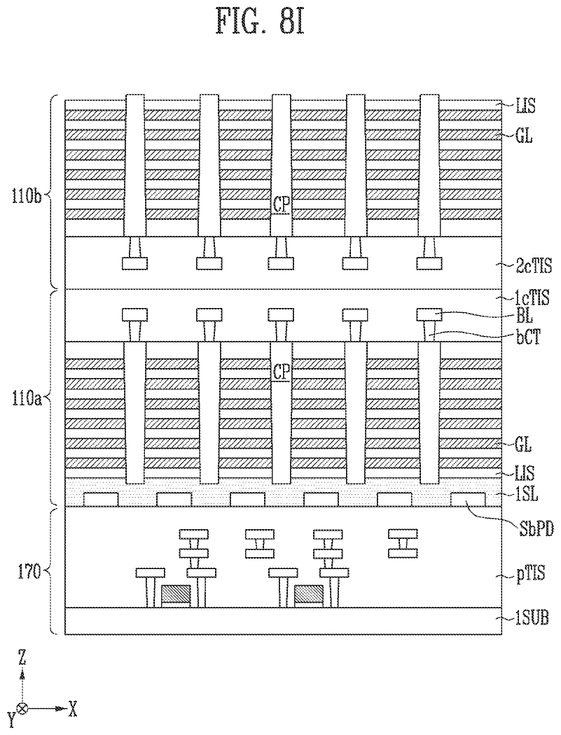

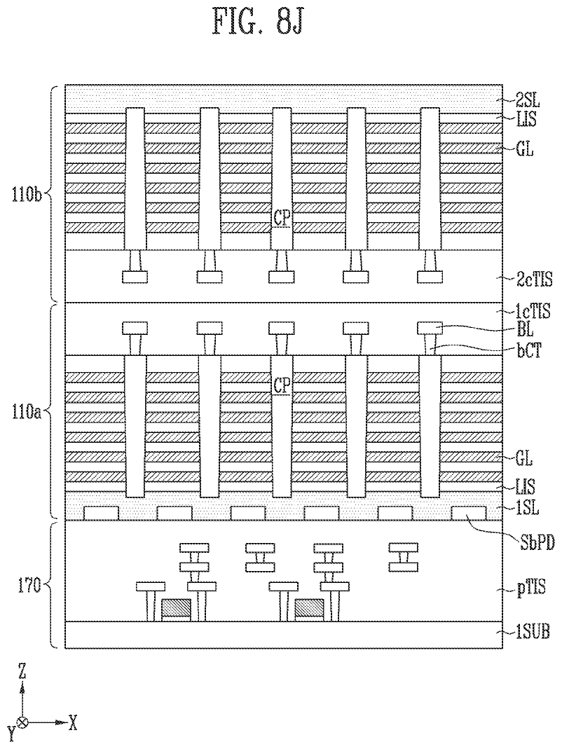

FIGS. 8A to 8J are diagrams illustrating steps of a method of manufacturing the memory device described above.

Referring to FIG. 8A, the transistors TR, the first contacts 1CT, and the peripheral lines PL may be formed on the first substrate 1SUB. Each of the transistors TR may include a gate insulating layer GI and a gate conductive layer CD. The gate insulating layer GI may be formed of an oxide layer. The gate conductive layer CD may be formed of at least one of tungsten (W), cobalt (Co), nickel (Ni), molybdenum (Mo), silicon (Si), and polysilicon (poly-Si), and may be formed of various other conductive layers. The first contacts 1CT and the peripheral lines PL may also be formed of a conductive layer. A portion of the first contacts 1CT may contact a source or a drain of the transistors TR, and may connect some of the peripheral lines PL positioned in different layers to each other. Some of the peripheral lines PL positioned on the same layer may be electrically connected to each other. The peripheral gap fill layer pTIS may be formed between the transistors TR, the first contacts 1CT, and the peripheral lines PL.

Referring to FIG. 8B, in order to form the first memory cell array, a first buffer layer 1BF may be formed on a second substrate 2SUB. Alternately-stacked line insulating layers LIS and gate lines GL are overlaid the first buffer layer 1BF. Cell plugs CP, which extend through, i.e., pass through the line insulating layers LIS and the gate lines GL may be formed. The line insulating layers LIS may be formed of an oxide layer. The gate lines GL may be formed of at least one of tungsten (W), cobalt (Co), nickel (Ni), molybdenum (Mo), silicon (Si), and polysilicon (poly-Si), but may be formed of various other conductive layers. Cell plugs CP may be formed in first vertical holes 1VH passing through the line insulating layers LIS and the gate lines GL.

Referring to plan view 81 of the cell plugs CP, which are formed in the XY plane and extend downwardly through the alternately-stacked layers in the Z-direction, each of the cell plugs CP may include a core pillar CR, a channel layer CH formed around the core pillar CR, and a memory layer ML formed around the channel layer CH. The memory layer ML may include a tunnel isolation layer TX, a charge trap layer CA, and a blocking layer BX. The core pillar CR may have a cylindrical shape and may be formed of either an insulating or conductive material. The channel layer CH may have a cylindrical shape surrounding a side surface of the core pillar CR and may be formed of polysilicon. The tunnel isolation layer TX may have a cylindrical shape surrounding a side surface of the channel layer CH and may be formed of an oxide layer. The charge trap layer CA may have a cylindrical shape surrounding a side surface of the tunnel isolation layer TX and may be formed of a nitride layer. The blocking layer BX may have a cylindrical shape surrounding a side surface of the charge trap layer CA and may be formed of an oxide layer.

Because the second substrate 2SUB and the first buffer layer 1BF are required to be removed in a subsequent process, the first buffer layer 1BF may be formed of a material of which an etch selectivity is higher than that of the line insulating layer LIS and the cell plug CP.

Referring to FIG. 8C, a first insulating layer 1TIS may be formed on the entire structure including the cell plugs CP, and bit line contacts bCT contacting the cell plugs CP by passing through the first insulating layer 1TIS may be formed. The first insulating layer 1TIS may be formed of an oxide layer, and the bit line contacts bCT may be formed of a conductive layer. Subsequently, a second insulating layer 2TIS and the bit lines BL may be formed on the bit line contacts bCT and the first insulating layer 1TIS. The second insulating layer 2TIS may be formed of an oxide layer, and the bit lines BL may be formed of a conductive layer. The second insulating layer 2TIS may be formed on the bit line contacts bCT and the first insulating layer 1TIS. Trenches Tc, exposing the bit line contacts bCT may be formed. A width of each of the trenches Tc may be wider than a width of each of the bit line contacts bCT. A conductive layer may be formed on the trenches Tc and the second insulating layer 2TIS to fill an inside of the trenches Tc, and then an etching process or a planarization process may be performed until the second insulating layer 2TIS is exposed. A third insulating layer 3TIS may be formed on the bit lines BL and the second insulating layer 2TIS, and thus a first cell interlayer insulating layer 1cTIS including the first to third insulating layers 1TIS to 3TIS may be formed. Accordingly, the first memory cell array 110a including the cell plugs CP may be formed.

Referring to FIG. 8D, the second memory cell array 110b may be formed on a third substrate 3SUB. The second memory cell array 110b may be formed in the same structure as the first memory cell array 110a of FIG. 8C. For example, a second buffer layer 2BF may be formed on the third substrate 3SUB, and the line insulating layers LIS and the gate lines GL alternately stacked on the second buffer layer 2BF, and cell plugs CP passing through the line insulating layers LIS and the gate lines GL may be formed. The line insulating layers LIS may be formed of an oxide layer, and the gate lines GL may be formed of at least one of tungsten (W), cobalt (Co), nickel (Ni), molybdenum (Mo), silicon (Si), and polysilicon (poly-Si), and may be formed of various other conductive layers. The cell plugs CP may be formed in the same structure as the cell plugs CP described with reference to FIG. 8B. In the second memory cell array 110b, the bit lines BL and the bit line contacts bCT may be covered with a second cell interlayer insulating layer 2cTIS.

Referring to FIG. 8E, the first memory cell array 110a may contact on the second memory cell array 110b. For example, the first memory cell array 110a is positioned at a lower portion and the second substrate 2SUB is positioned at an upper portion by turning the entire structure described with reference to FIG. 8C. Subsequently, the first cell interlayer insulating layer 1cTIS of the first memory cell array 110a may contact on the second cell interlayer insulating layer 2cTIS of the second memory cell array 110b.

Referring to FIG. 8F, the second substrate 2SUB of FIG. 8E and the first buffer layer 1BF positioned on the first memory cell array 110a are removed. The second substrate 2SUB and the first buffer layer 1BF may be removed through a wet etching process. When the first buffer layer 1BF is removed and the line insulating layer LIS and the cell plugs CP are exposed, the first source line 1SL may be formed on the exposed cell plugs CP and line insulating layer LIS. The first source line 1SL may be formed of a conductive layer. For example, the first source line 1SL may be formed of polysilicon. After the first source line 1SL is formed, openings OP may be formed by removing a portion of an upper portion of the first source line 1SL. The openings OP may have a rectangular, square, circular, or oval shape and may be spaced apart from each other.

Referring to FIG. 8G, the source bonding pads SbPD may be formed in the openings OP. The source bonding pads SbPD may be formed of a dielectric material. In one embodiment, a dielectric layer may be formed over the entire structure so that the openings OP are filled with a dielectric material. A planarization process may then be performed so that an upper surface of the first source line 1SL and the source bonding pads SbPD are substantially flat, wherein flatness or surface roughness may be quantified by computing the arithmetical mean value for a randomly sampled area.

Referring to FIG. 8H, a stack structure of the first and second memory cell arrays 110a and 110b may make contact with the peripheral circuit 170 described with reference to FIG. 8A. For example, the first memory cell array 110a is positioned at a lower portion and the second memory cell array 110b is positioned at an upper portion by turning the entire structure described with reference to FIG. 8G over. The source bonding pads SbPD included in the first source line 1SL of the first memory cell array 110a may contact the peripheral gap fill layer pTIS of the peripheral circuit 170. Because the source bonding pads SbPD are included in the first source line 1SL and the source bonding pads SbPD contact the peripheral gap fill layer pTIS, bonding strength between the first source line 1SL and the peripheral circuit 170 may be increased.

Referring to FIG. 8I, the third substrate 3SUB of FIG. 8H and the second buffer layer 2BF positioned on the second memory cell array 110b may be removed. For example, the third substrate 3SUB and the second buffer layer 2BF may be removed through a wet etching process, but the present disclosure is not limited to the wet etching process. When the second buffer layer 2BF is removed, the line insulating layer LIS and the cell plugs CP included in the second memory cell array 110b may be exposed.

Referring to FIG. 8J, the second source line 2SL may be formed on the exposed cell plugs CP and line insulating layer LIS. The second source line 2SL may be formed of a conductive layer. For example, the second source line 2SL may be formed of polysilicon.

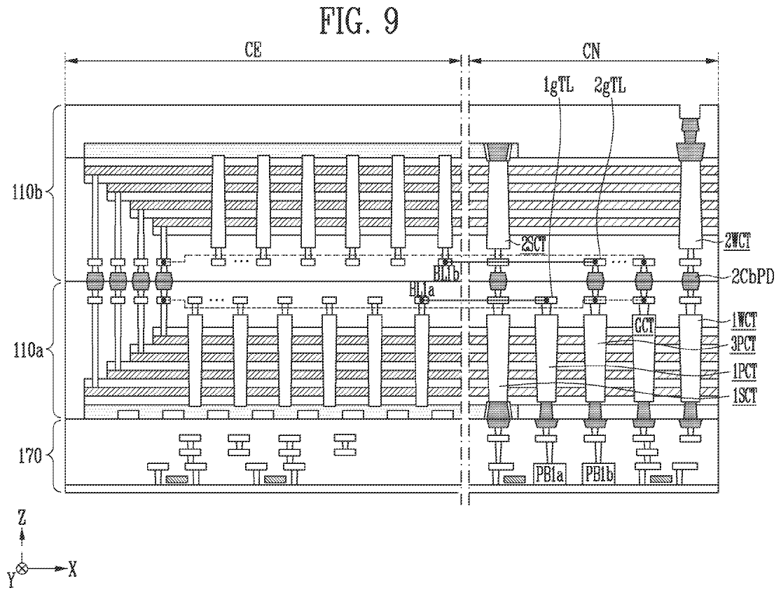

FIG. 9 is a vertical cross-sectional view illustrating a memory device according to a second embodiment of the present disclosure.

Referring to FIG. 9, because the memory device according to the second embodiment includes a structure similar to that of the memory device according to the first embodiment, a description of the same structure depicted in FIGS. 8A to 8J as overlapping that of the first embodiment is omitted.

In the second embodiment depicted in FIG. 9, a position of the bit lines included in the first bit line group BL1a of the first memory cell array 110a and a position of the bit lines included in the second bit line group BL1b of the second memory cell array 110b match each other in the Z direction. However, in the second embodiment, the position of the bit lines included in the first bit line group BL1a of the first memory cell array 110a and the position of the bit lines included in the second bit line group BL1b of the second memory cell array 110b may not match each other in the Z direction. For example, the bit lines included in the second bit line group BL1b of the second memory cell array 110b may be positioned on a region between the bit lines included in the first bit line group BL1a of the first memory cell array 110a.

In the second embodiment, the bit lines included in the first bit line group BL1a may be electrically blocked from the bit lines included in the second bit line group BL1b. For example, in the connection region CN of the first memory cell array 110a, first page buffer contacts 1PCT for electrically connecting the first bit line group BL1a included in the first memory cell array 110a and page buffers PB1a of the peripheral circuit 170, and third page buffer contacts 3PCT for electrically connecting the second bit line group BL1b included in the second memory cell array 110b and page buffers PB1b of the peripheral circuit 170 may be included. The page buffers PB1a connected to the first page buffer contacts 1PCT are different from the page buffers PB1b connected to the third page buffer contacts 3PCT. The first page buffer contacts 1PCT may be electrically connected to the first bit line group BL1a included in the first memory cell array 110a through the first gate transmission line 1gTL. The third page buffer contacts 3PCT may be electrically connected to the second bit line group BL1b included in the second memory cell array 110b through the second contact bonding pads 2CbPD and second gate transmission lines 2gTL.

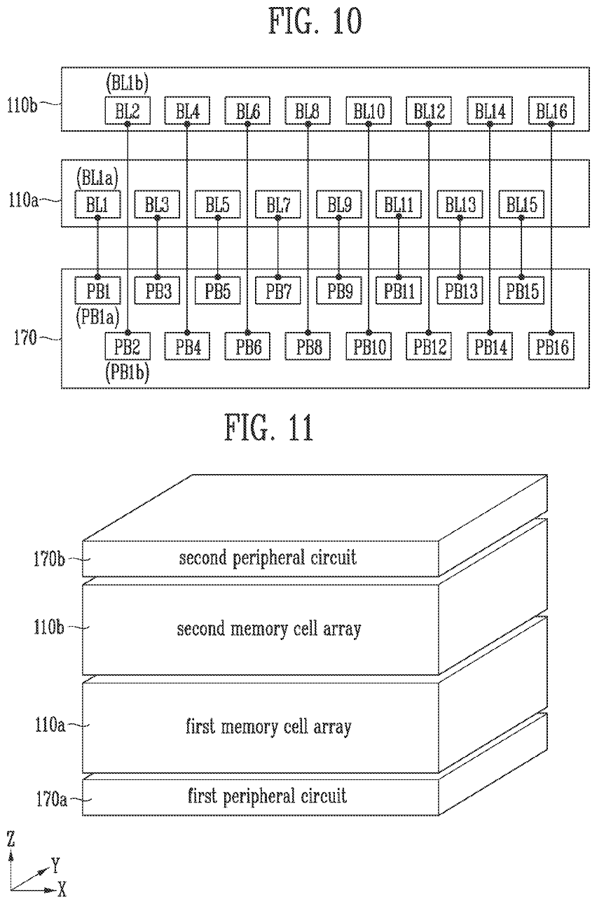

FIG. 10 is a diagram illustrating a layout of the memory device according to the second embodiment of the present disclosure.

Referring to FIGS. 9 and 10, because the first bit line group BL1a included in the first memory cell array 110a and the second bit line group BL1b included in the second memory cell array 110b are electrically separated from each other, the first bit line group BL1a included in the first memory cell array 110a may include odd bit lines BL1, BL3, BL5, . . . , and BL15, and the second bit line group BL1b included in the second memory cell array 110b may include even bit lines BL2, BL4, BL6, . . . , and BL16. FIG. 10 shows 16, bit lines, however, the number of bit lines may change according to the memory device. For example, the first bit line BL1 included in the first memory cell array 110a may be connected to the first page buffer PB1 included in the peripheral circuit 170, and the second bit line BL2 included in the second memory cell array 110b may be connected to the second page buffer PB2 included in the peripheral circuit 170. In such a method, the fifteenth bit line BL15 included in the first memory cell array 110a may be connected to the fifteenth page buffer PB15 included in the peripheral circuit 170, and the sixteenth bit line BL16 included in the second memory cell array 110b may be connected to the sixteenth page buffer PB16 included in the peripheral circuit 170.

FIG. 11 is a perspective view illustrating a memory device according to a third embodiment of the present disclosure.

Referring to FIG. 11, in the memory device according to the third embodiment, structures manufactured on four different substrates may be stacked on top of each other. For example, the first memory cell array 110a may be stacked on a first peripheral circuit 170a. A second memory cell array 110b may be stacked on the first memory cell array 110a, before or after the first memory cell array 110a is stacked of the first peripheral circuit. A second peripheral circuit 170b may be stacked on the second memory cell array 110b, before or after the second memory cell array 110b is stacked on the first memory cell array 110a.

The first and second peripheral circuits 170a and 170b may each be embodied as the peripheral circuit 170 shown in FIG. 1. The first and second memory cell arrays 110a and 110b may each be embodied as the memory cell array 110 shown in FIG. 1.

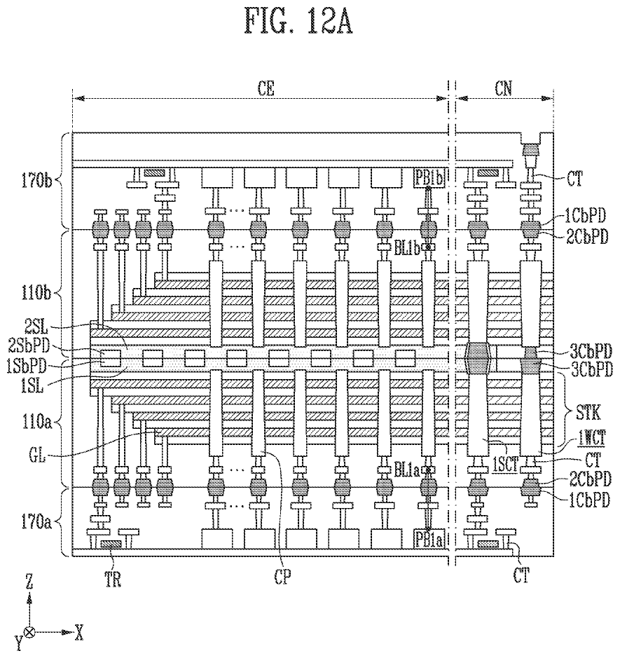

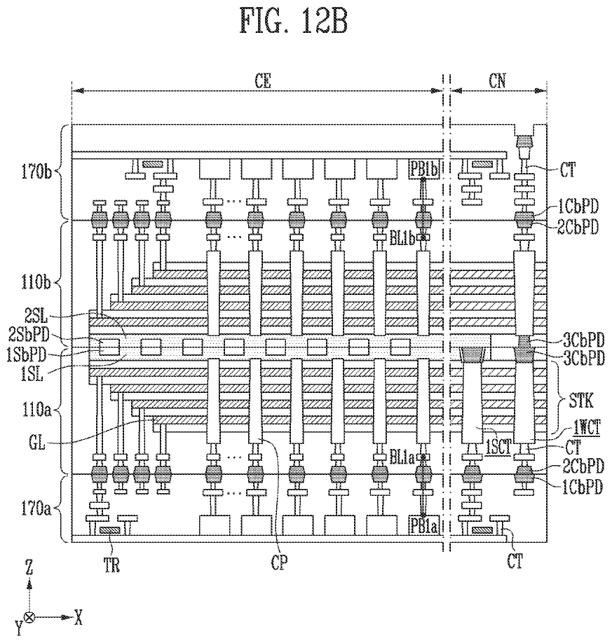

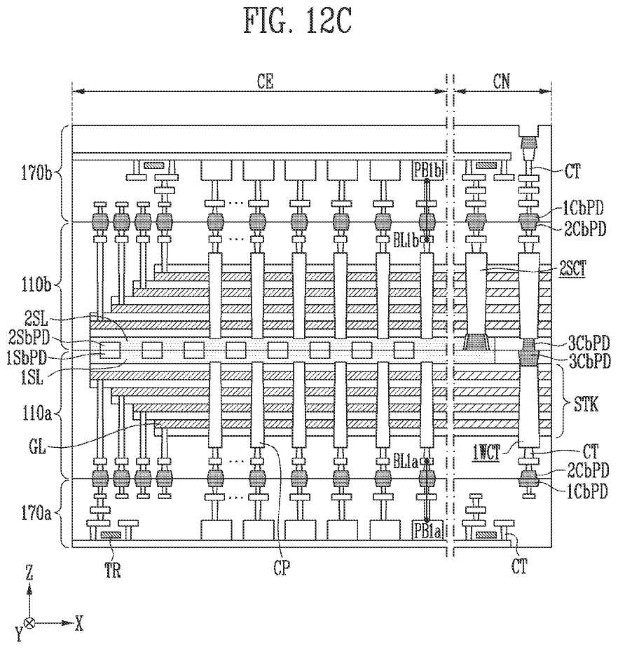

FIGS. 12A to 12C are cross-sectional views illustrating the memory device according to the third embodiment of the present disclosure.

Referring to FIGS. 11 and 12A, the page buffers PB1a may be included in the cell region CE of the first peripheral circuit 170a. The transistors TR electrically connected to the gate lines GL of the first memory cell array 110a may also be included in the cell region CE. In the connection region CN of the first peripheral circuit 170a, transistors configured to generate and output the source voltage may be included. The first contact bonding pads 1CbPD included in the first peripheral circuit 170a may be exposed through an upper surface of the first peripheral circuit 170a.

The first memory cell array 110a may be implemented in a structure similar to that of the second memory cell array 110b of FIG. 5 of the first embodiment. For example, the first memory cell array 110a shown in FIG. 12A may include the second contact bonding pads 2CbPD, the first bit line group BL1a, a stack STK, the first source line 1SL, the third contact bonding pads 3CbPD, the cell plugs CP, the first source contact 1SCT, and the first power contact 1WCT.

The second contact bonding pads 2CbPD may be positioned under the first memory cell array 110a and may respectively contact an upper surface of the first contact bonding pads 1CbPD of the first peripheral circuit 170a. The stack STK may be positioned on the second contact bonding pads 2CbPD and may include insulating layers, gate lines, and sacrificial layers. For example, the insulating layers and the gate lines may be alternately stacked in the cell region CE of the stack STK, and the insulating layers and the sacrificial layers may be alternately stacked in the connection region CN. The stack STK of the cell region CE may have a step structure in which a length becomes shorter from an upper portion to a lower portion. The cell plugs CP may pass through the stack STK of the cell region CE. The bit lines BL1a may be positioned between the cell plugs CP and the second contact bonding pads 2CbPD. The cell plugs CP, the first bit line group BL1a, the second contact bonding pads 2CbPD, the first contact bonding pads 1CbPD, and the page buffers PB1a may be electrically connected to each other through the contacts CT. The gate lines GL of the cell region CE may also be electrically connected to the second contact bonding pads 2CbPD, the first contact bonding pads 1CbPD, and the transistors of the first peripheral circuit 170a through the contacts CT. A portion of an upper portion of the cell plugs CP may be in contact with the first source line 1SL. First source bonding pads 1SbPD may be included in the first source line 1SL. For example, the first source bonding pads 1SbPD may be exposed through the upper surface of the first source line 1SL. The first source contact 1SCT and the first power contact 1WCT may pass through the stack STK of the connection region CN, and may be positioned between the second contact bonding pads 2CbPD and the third contact bonding pads 3CbPD.

The second memory array 110b may be implemented in a structure that is symmetrical to or the same as the first memory cell array 110a. For example, the second memory cell array 110b may be implemented in a structure that is symmetrical to the first memory cell array 110a with respect to the XY plane. Therefore, the second memory cell array 110b and the first memory cell array 110a may be in contact with each other through the second source bonding pads 2SbPD and the third contact bonding pads 3CbPD. In addition, the first and second memory cell arrays 110a and 110b may also be in contact with each other through cell interlayer insulating layers.

The second peripheral circuit 170b may be implemented in a structure that is symmetrical to the first peripheral circuit 170a and may contact on the second memory cell array 110b. The page buffers PB1b of the second peripheral circuit 170b may be electrically connected to the second bit line group BL1b of the second memory cell array 110b through the first contact bonding pads 1CbPD included in the second peripheral circuit 170b, the second contact bonding pads 2CbPD included in the second memory cell array 110b, and the contacts CT.

That is, in the memory device according to the third embodiment, the page buffers PB1a of the first peripheral circuit 170a may be connected to the bit lines included in the first bit line group BL1a of the first memory cell array 110a, and the page buffers PB1b of the second peripheral circuit 170b may be connected to the bit lines included in the second bit line group BL1b of the second memory cell array 110b.

Referring to FIG. 12B, the source voltage applied to the first source line 1SL of the first memory cell array 110a and the second source line 2SL of the second memory cell array 110b may be supplied through the first peripheral circuit 170a. For example, the first source contact 1SCT connected to the first peripheral circuit 170a may be positioned only in the connection region CN of the first memory cell array 110a. Therefore, the source voltage generated in the first peripheral circuit 170a may be supplied to the first and second source lines 1SL and 2SL through the first source contact 1SCT of the first memory cell array 110a. Because remaining structures except for the first source contact 1SCT are the same as those shown in FIG. 12A, an overlapping description is omitted.

Referring to FIG. 12C, the source voltage applied to the first source line 1SL of the first memory cell array 110a and the second source line 2SL of the second memory cell array 110b may be supplied through the second peripheral circuit 170b. For example, the second source contact 2SCT connected to the second peripheral circuit 170b may be positioned only in the connection region CN of the second memory cell array 110b. Therefore, the source voltage generated in the second peripheral circuit 170b may be supplied to the first and second source lines 1SL and 2SL through the second source contact 2SCT of the second memory cell array 110b. Because remaining structures except for the second source contact 2SCT are the same as those shown in FIG. 12A, a redundant description of them is omitted in the interest of brevity.

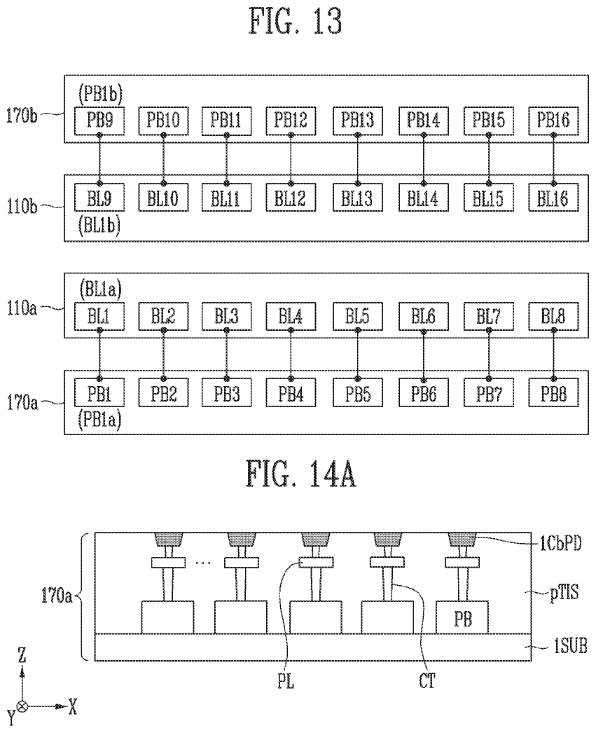

FIG. 13 is a diagram illustrating a layout of the memory device according to the third embodiment of the present disclosure.

Referring to FIGS. 12A to 12C and 13, the first peripheral circuit 170a may include first to eighth page buffers PB1 to PB8, and the second peripheral circuit 170b may include ninth to sixteenth page buffers PB9 to PB16. The number of page buffers PB1a and PB1b included in each of the first and second peripheral circuits 170a and 170b is not limited to the number shown in FIG. 13.

The first memory cell array 110a may include first to eighth bit lines BL1 to BL8 included in the first bit line group BL1a, and the second memory cell array 110b may include ninth to sixteenth bit lines BL9 to BL16 included in the second bit line group BL1b. The number of bit lines BL1 to BL16 included in each of the first and second memory cell arrays 110a and 110b is not limited to the number shown in FIG. 13.

The first to eighth page buffers PB1 to PB8 included in the first peripheral circuit 170a may be respectively connected to the first to eighth bit lines BL1 to BL8 included in the first memory cell array 110a, and the ninth to sixteenth page buffers PB9 to PB16 included in the second peripheral circuit 170b may be respectively connected to the ninth to sixteenth bit lines BL9 to BL16 included in the second memory cell array 110b.

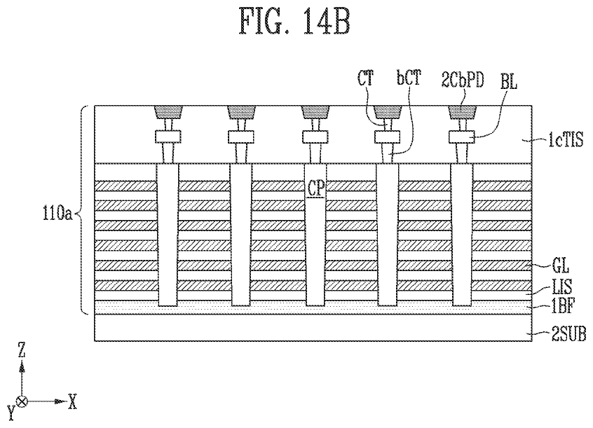

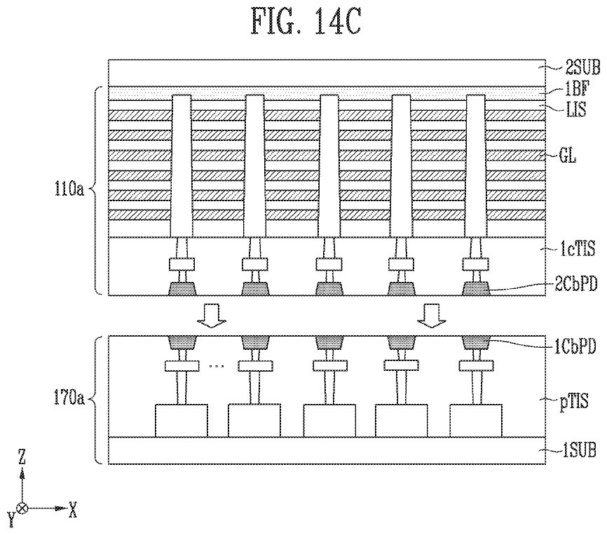

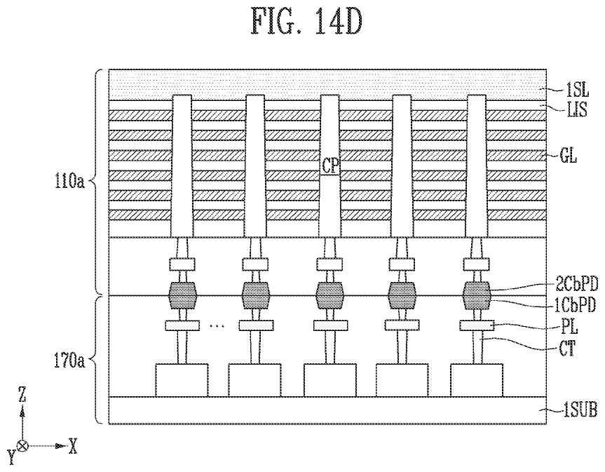

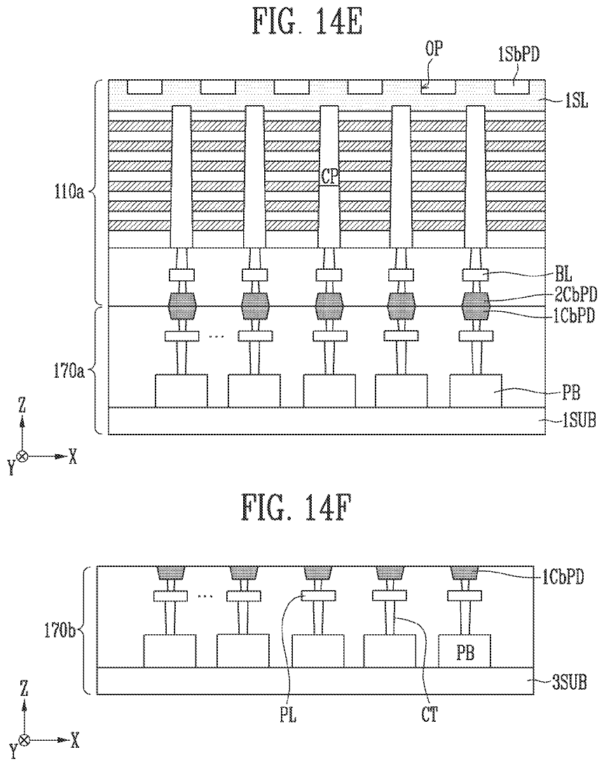

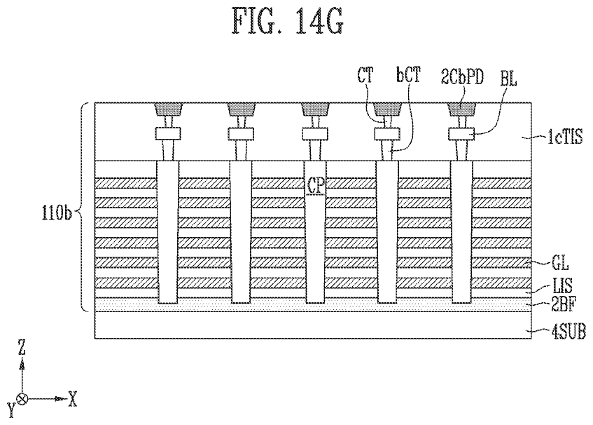

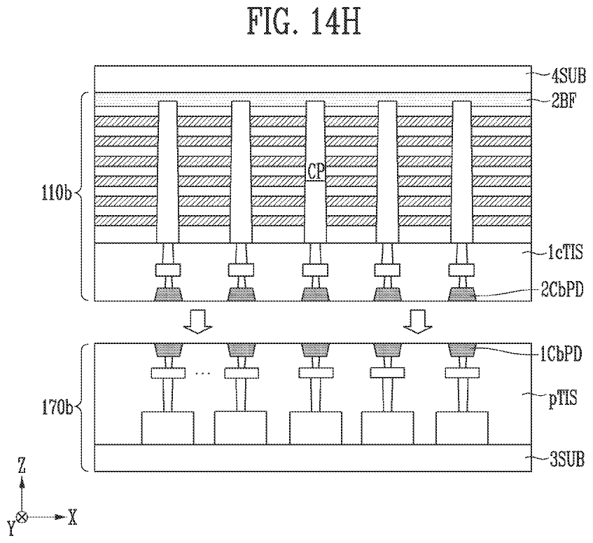

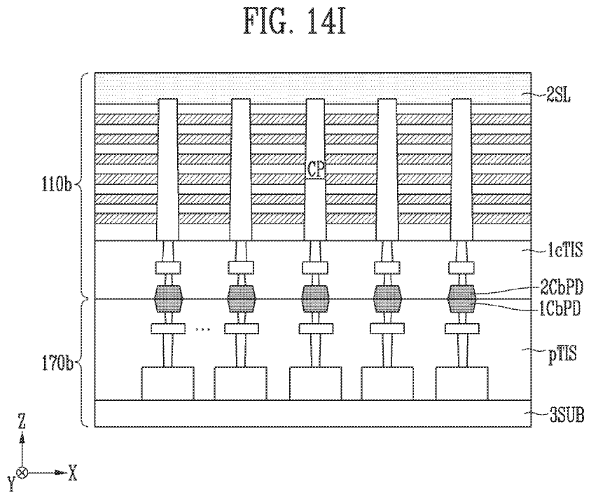

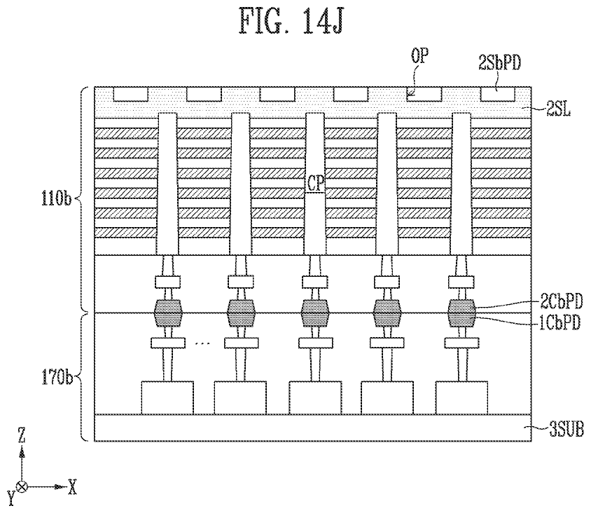

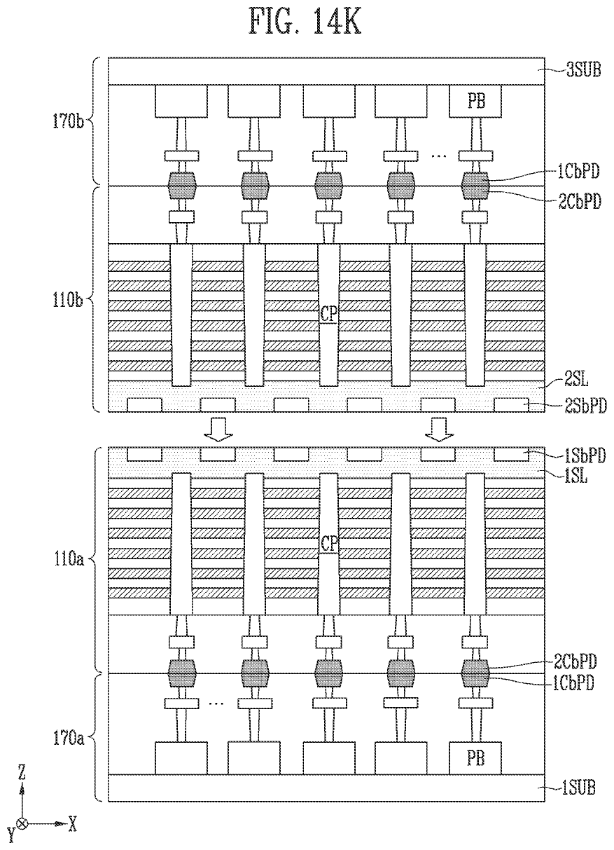

FIGS. 14A to 14K are diagrams illustrating steps of a method of manufacturing the memory device according to the third embodiment of the present disclosure. Among structures shown in FIGS. 14A to 14K, a description of structures that are shown in FIGS. 8A to 8J and described above is omitted in the interest of brevity.

Referring to FIG. 14A, the first peripheral circuit 170a may be formed on the first substrate 1SUB. The first peripheral circuit 170a may include the page buffers PB, the contacts CT, the peripheral lines PL, and the first contact bonding pads 1CbPD, and may further include at least one circuit among circuits included in the peripheral circuit 170 described above with reference to FIG. 1. The contacts CT, the peripheral lines PL, and the first contact bonding pads 1CbPD may be formed of a conductive material. A region around the page buffers PB, the contacts CT, the peripheral lines PL, and the first contact bonding pads 1CbPD may be filled with the peripheral gap fill layer pTIS. The peripheral gap fill layer pTIS may be formed as an insulating layer. For example, the peripheral gap fill layer pTIS may be formed of an oxide layer, and more specifically, may be formed of a silicon oxide layer.

Referring to FIG. 14B, the first memory cell array 110a may be formed on the second substrate 2SUB. For example, the first memory cell array 110a may include the first buffer layer 1BF, the line insulating layers LIS, the gate lines GL, the cell plugs CP, the bit line contacts bCT, the bit lines BL, the contacts CT, the second contact bonding pads 2CbPD, and the first cell interlayer insulating layer 1cTIS positioned on the second substrate 2SUB. For example, the first buffer layer 1BF may be formed of a material having an etch selectivity with respect to the line insulating layers LIS and the cell plugs CP, and may cover the second substrate 2SUB. The line insulating layers LIS and the gate lines GL may be alternately stacked on the first buffer layer 1BF. The line insulating layers LIS may be an oxide layer, and the gate lines GL may be a conductive layer. The cell plugs CP may contact the first buffer layer 1BF by passing through the line insulating layers LIS and the gate lines GL. The cell plugs CP may be formed in the same structure as the cell plug CP described with reference to FIG. 8B. The bit line contacts bCT, the bit lines BL, the contacts CT, and the second contact bonding pads 2CbPD may be positioned on the cell plugs CP. The second contact bonding pads 2CbPD may be formed of the same material as the first contact bonding pads 1CbPD of FIG. 14A. The first cell interlayer insulating layer 1cTIS may be formed around the bit line contacts bCT, the bit lines BL, the contacts CT, and the second contact bonding pads 2CbPD. The first cell interlayer insulating layer 1cTIS may be formed as an insulating layer. For example, the first cell interlayer insulating layer 1cTIS may be formed of an oxide layer, and more specifically, may be formed of a silicon oxide layer.

Referring to FIG. 14C, the first memory cell array 110a may contact on the first peripheral circuit 170a. For example, the second contact bonding pads 2CbPD are positioned at a lower portion and the second substrate 2SUB is positioned at an upper portion by turning the entire structure described with reference to FIG. 14B over. An upper surface of the first peripheral circuit 170a and a lower surface of the first memory cell array 110a are in contact with each other, and a bonding process of a heat treatment method may be performed. Due to the bonding process, the peripheral gap fill layer pTIS of the first peripheral circuit 170a and the first cell interlayer insulating layer 1cTIS of the first memory cell array 110a may be in contact with each other, and the first contact bonding pads 1CbPD of the first peripheral circuit 170a and the second contact bonding pads 2CbPD of the first memory cell array 110a may be in contact with each other.

Referring to FIG. 14D, the second substrate 2SUB of FIG. 14C and the first buffer layer 1BF of FIG. 14C positioned on the first memory cell array 110a may be removed. For example, a wet etching process for removing the second substrate 2SUB may be performed. The first buffer layer 1BF may protect the cell plugs CP when the second substrate 2SUB is removed. The first buffer layer 1BF may be removed by a wet or dry etching process. When the first buffer layer 1BF is removed, a portion of the line insulating layer LIS and the cell plugs CP may be exposed. Subsequently, the first source line 1SL covering the exposed line insulating layer LIS and cell plugs CP may be formed.

Referring to FIG. 14E, the openings OP spaced apart from each other may be formed by etching a portion of an upper portion of the first source line 1SL. For example, the openings OP may be formed by performing a dry etching process. The openings OP may have a depth shallower than a thickness of the first source line 1SL. When the openings OP are formed, the first source bonding pads 1SbPD may be formed within the openings OP. The first source bonding pads 1SbPD may be formed of a dielectric layer.

Referring to FIG. 14F, the second peripheral circuit 170b may be formed on the third substrate 3SUB. The second peripheral circuit 170b may include the page buffers PB, the contacts CT, the peripheral lines PL, and the first contact bonding pads 1CbPD, and may further include at least one circuit among the circuits included in the peripheral circuit 170 described with reference to FIG. 1. The contacts CT, the peripheral lines PL, and the first contact bonding pads 1CbPD may be formed of a conductive material. A region around the page buffers PB, the contacts CT, the peripheral lines PL, and the first contact bonding pads 1CbPD may be filled with the peripheral gap fill layer pTIS. The peripheral gap fill layer pTIS may be formed as an insulating layer. For example, the peripheral gap fill layer pTIS may be formed of an oxide layer, and more specifically, may be formed of a silicon oxide layer.

Referring to FIG. 14G, the second memory cell array 110b may be formed on a fourth substrate 4SUB. For example, the second memory cell array 110b may include the second buffer layer 2BF, the line insulating layers LIS, the gate lines GL, the cell plugs CP, the bit line contacts bCT, the bit lines BL, the contacts CT, the second contact bonding pads 2CbPD, and the first cell interlayer insulating layer 1cTIS positioned on the fourth substrate 4SUB. For example, the first buffer layer 1BF may be formed of a material having an etch selectivity with respect to the line insulating layers LIS and the cell plugs CP, and may cover the second substrate 2SUB. The alternately stacked line insulating layers LIS and the gate lines GL may be overlaid the first buffer layer 1BF. The line insulating layers LIS may be an oxide layer. The gate lines GL may be formed as a conductive layer. The cell plugs CP may contact the first buffer layer 1BF by passing through the line insulating layers LIS and the gate lines GL. The cell plugs CP may be formed in the same structure as the cell plug CP described with reference to FIG. 8B.

The bit line contacts bCT, the bit lines BL, the contacts CT, and the second contact bonding pads 2CbPD may be positioned or located on the cell plugs CP. The second contact bonding pads 2CbPD may be formed of the same material as the first contact bonding pads 1CbPD of FIG. 14A.

The first cell interlayer insulating layer 1cTIS may be formed around the bit line contacts bCT, the bit lines BL, the contacts CT, and the second contact bonding pads 2CbPD. The first cell interlayer insulating layer 1cTIS may be formed as an insulating layer. For example, the first cell interlayer insulating layer 1cTIS may be formed of an oxide layer, and more specifically, may be formed of a silicon oxide layer.

Referring to FIG. 14H, the second memory cell array 110b may contact the second peripheral circuit 170b. For example, the second contact bonding pads 2CbPD are positioned at a lower portion and the fourth substrate 4SUB is positioned at an upper portion by turning the entire structure described with reference to FIG. 14G over. An upper surface of the second peripheral circuit 170b and a lower surface of the second memory cell array 110b may be in contact with each other, and a bonding process of a heat treatment method may be performed. Due to the bonding process, the peripheral gap fill layer pTIS of the second peripheral circuit 170b and the first cell interlayer insulating layer 1cTIS of the second memory cell array 110b may be in contact with each other, and the first contact bonding pads 1CbPD of the second peripheral circuit 170b and the second contact bonding pads 2CbPD of the second memory cell array 110b may be in contact with each other.

Referring to FIG. 14I, the fourth substrate 4SUB of FIG. 14h and the second buffer layer 2BF of FIG. 14h positioned on the second memory cell array 110b may be removed. For example, a wet etching process for removing the fourth substrate 4SUB may be performed. The second buffer layer 2BF may protect the cell plugs CP when the fourth substrate 4SUB is removed. The second buffer layer 2BF may be removed by a wet or dry etching process. When the second buffer layer 2BF is removed, a portion of the line insulating layer LIS and the cell plugs CP may be exposed. Subsequently, the second source line 2SL covering the exposed line insulating layer LIS and cell plugs CP may be formed.

Referring to FIG. 14J, the openings OP that are spaced apart from each other may be formed by etching a portion of an upper portion of the second source line 2SL. For example, the openings OP may be formed by performing a dry etching process. The openings OP may have a depth shallower than a thickness of the second source line 2SL. When the openings OP are formed, the second source bonding pads 2SbPD may be formed within the openings OP. The second source bonding pads 1SbPD may be formed of a dielectric layer.

Referring to FIG. 14K, the second contact bonding pads 2CbPD are positioned at a lower portion and the third substrate 3SUB is positioned at an upper portion by turning the entire structure described with reference to FIG. 14J. A lower surface of the turned structure is joined to an upper portion of the entire structure described with reference to FIG. 14E. For example, the first source bonding pads 1SbPD of the first memory cell array 110a and the second source bonding pads 2SbPD of the second memory cell array 110b may contact each other.

Since the first source bonding pads 1SbPD included in the first source line 1SL of the first memory cell array 110a are in contact with the second source bonding pads 2SbPD included in the second source line 2SL of the second memory cell array 110b, bonding strength of the first source line 1SL and the second source line 2SL may also be increased.

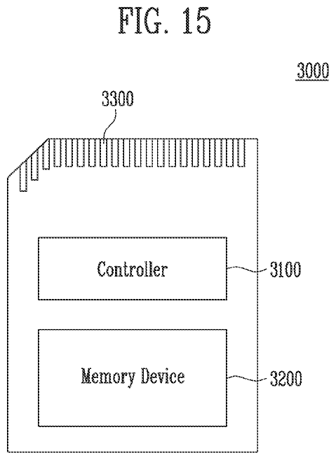

FIG. 15 is a diagram illustrating a memory card system to which a memory device of the present disclosure is applied.

Referring to FIG. 15, the memory card system 3000 includes a controller 3100, a memory device 3200, and a connector 3300.

The controller 3100 is connected to the memory device 3200. The controller 3100 is configured to access the memory device 3200. For example, the controller 3100 may be configured to control a program, read, or erase operation of the memory device 3200 or to control a background operation. The controller 3100 is configured to provide an interface between the memory device 3200 and a host. The controller 3100 is configured to drive firmware for controlling the memory device 3200. For example, the controller 3100 may include components such as a random access memory (RAM), a processing unit, a host interface, a memory interface, and an error correction circuit.

The controller 3100 may communicate with an external device through the connector 3300. The controller 3100 may communicate with an external device (for example, the host) according to a specific communication standard. For example, the controller 3100 is configured to communicate with an external device through at least one of various communication standards such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. For example, the connector 3300 may be defined by at least one of the various communication standards described above.

The memory device 3200 may include a plurality of memory cells, and may be configured identically to the memory device 100 shown in FIG. 1.

The controller 3100 and the memory device 3200 may be integrated into one semiconductor device to configure a memory card. For example, the controller 3100 and the memory device 3200 may be integrated into one semiconductor device to configure a memory card such as a PC card (personal computer memory card international association (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), and a universal flash storage (UFS).

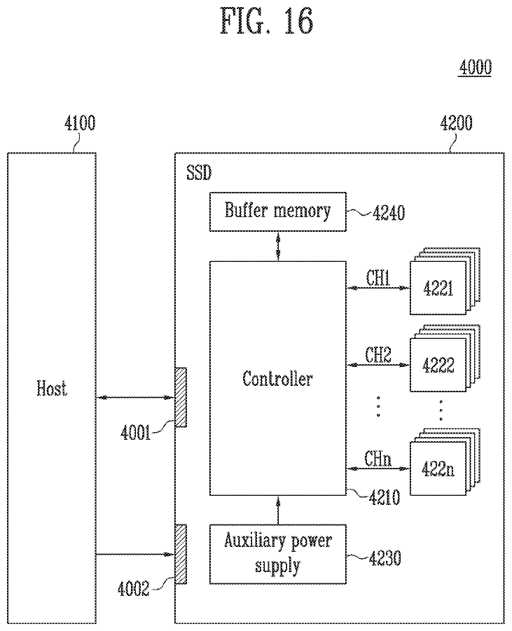

FIG. 16 is a diagram illustrating a solid state drive (SSD) system to which a memory device of the present disclosure is applied.

Referring to FIG. 16, the SSD system 4000 includes a host 4100 and an SSD 4200. The SSD 4200 exchanges a signal with the host 4100 through a signal connector 4001 and receives power through a power connector 4002. The SSD 4200 includes a controller 4210, a plurality of memory devices 4221 to 422n, an auxiliary power supply 4230, and a buffer memory 4240.

The controller 4210 may control the plurality of memory devices 4221 to 422n in response to the signal received from the host 4100. For example, the signal may be signals based on an interface between the host 4100 and the SSD 4200. For example, the signal may be a signal defined by at least one of interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 is connected to the host 4100 through the power connector 4002. The auxiliary power supply 4230 may receive a power voltage from the host 4100 and charge the power voltage. The auxiliary power supply 4230 may provide a power voltage of the SSD 4200 when power supply from the host 4100 is not smooth. For example, the auxiliary power supply 4230 may be positioned in the SSD 4200 or may be positioned outside the SSD 4200. For example, the auxiliary power supply 4230 may be positioned on a main board and may provide auxiliary power to the SSD 4200.

The buffer memory 4240 operates as a buffer memory of the SSD 4200. For example, the buffer memory 4240 may temporarily store data received from the host 4100 or data received from the plurality of memory devices 4221 to 422n, or may temporarily store meta data (for example, a mapping table) of the memory devices 4221 to 422n. The buffer memory 4240 may include a volatile memory such as a DRAM, an SDRAM, a DDR SDRAM, and an LPDDR SDRAM, or a nonvolatile memory such as an FRAM, a ReRAM, an STT-MRAM, and a PRAM.

What is claimed is:

1. A memory device comprising:
a first peripheral circuit comprising first page buffers, the first peripheral circuit having a cell region and a connection region;
a first memory cell array over the first peripheral circuit, the first memory cell array comprising first bit lines electrically connected to corresponding ones of the first page buffers; and
a second memory cell array over the first memory cell array and comprising second bit lines, which are electrically connected to corresponding ones of the first bit lines.

2. The memory device of claim 1, wherein the first memory cell array comprises:
a first source line in the cell region of the first peripheral circuit;
first gate lines over the first source line;
first cell plugs passing through the first gate lines, vertically between the first bit lines and the first source line;
the first bit lines coupled to the first cell plugs;
first page buffer contacts in the connection region of the first peripheral circuit and electrically connected to the first page buffers; and
first sub-bit lines electrically connecting the first page buffer contacts and the first bit lines, respectively.

3. The memory device of claim 2, wherein the second memory cell array comprises
second bit lines, second gate lines, a second source line, second cell plugs and second sub-bit lines.

4. The memory device of claim 2, wherein the first source line further includes spaced apart source bonding pads coupled to the first peripheral circuit.

5. The memory device of claim 4, wherein the source bonding pads are in contact with an upper surface of a peripheral gap fill layer, which covers transistors in the first peripheral circuit.

6. The memory device of claim 4, wherein each source bonding pad comprises a dielectric layer.

7. The memory device of claim 4, wherein each of the source bonding pads is configured of a plurality of different dielectric layers.

8. The memory device of claim 4, wherein the source bonding pads have a horizontal cross-sectional shape, which is at least one of: substantially square, substantially rectangular, substantially circular, and substantially oval.

9. The memory device of claim 3, further comprising:
first gate transmission lines in the connection region of the first memory cell array and which is electrically connected to the first gate lines; and
gate line contacts in the connection region of the first memory cell array and which is configured to transmit word line voltages to the first gate transmission lines, which are received from the first peripheral circuit.

10. The memory device of claim 9, further comprising:
second gate transmission lines in the connection region of second memory cell array and which are configured to electrically connect the second gate lines and the first gate transmission lines.

11. The memory device of claim 3, further comprising:
a bonding pad in the connection region of the first memory cell array and configured to transmit a source voltage generated in the first peripheral circuit to the first source line;
a contact liner layer surrounding the bonding pad between the bonding pad and the first source line;
a first source contact contacting the bonding pad by passing through sacrificial layers stacked in the connection region of the first memory cell array; and
a second source contact in the connection region of the second memory cell array and configured to electrically connect the first source contact and the second source line.

12. The memory device of claim 1, further comprising:
an external power pad exposed on an upper portion of the second memory cell array;
a second power contact in the connection region of the second memory cell array and electrically connected to the external power pad; and
a first power contact in the connection region of the first memory cell array and configured to transmit external power supplied through the external power pad to the first peripheral circuit.

13. The memory device of claim 2, further comprising:
second page buffer contacts in the connection region of the first memory cell array, electrically connected to a portion of the first page buffers of the first peripheral circuit, and electrically isolated from the first bit lines.

14. The memory device of claim 13, further comprising:
third sub-bit lines in the connection region of the second memory cell region configured to electrically connect the second bit lines and the second page buffer contacts.

15. The memory device of claim 1, further comprising:
a second peripheral circuit over the second memory cell array.

16. The memory device of claim 15, wherein the first peripheral circuit comprises:
first contacts adjacent to each of the first page buffers; and
first contact bonding pads which are in contact with each of the first contacts and exposed through an upper surface of the first peripheral circuit.

17. The memory device of claim 16, wherein the first memory cell array comprises:
second contact bonding pads which are in contact with the first contact bonding pads;
first bit lines connected to the second contact bonding pads;
first gate lines on the first bit lines;
a first source line on the first gate lines;
first cell plugs passing through the first gate lines and extending between the first source line and a first bit line; and
first source bonding pads included in the first source line and exposed through an upper surface of the first source line.

18. The memory device of claim 17, wherein the second memory cell array comprises:
a second source line over the first memory cell array;
second source bonding pads in the second source line and respectively contacting the first source bonding pads through a lower surface of the second source line;
second gate lines over the second source line;
second bit lines over the second gate lines;
second cell plugs passing through the second gate lines and extending between the second bit lines and the second source line; and
third contact bonding pads connected to each of the second bit lines.

19. The memory device of claim 18, wherein the second peripheral circuit comprises:
fourth contact bonding pads respectively contacting the third contact bonding pads; and
second contacts respectively contacting the fourth contact bonding pads.

20. A memory device comprising:
a first peripheral circuit having a cell region and a connection region, the first peripheral circuit having first page buffers in the cell region;
a first memory cell array over the peripheral circuit and including first bit lines electrically connected to the first page buffers;
a second memory cell array over the first memory cell array and including second bit lines within the cell region; and
a second peripheral circuit over the second memory cell array and including second page buffers electrically connected to the second bit lines,
wherein the first memory cell array comprises:
a first source line positioned at an upper end of the first memory cell array; and
first source bonding pads included in the first source line and exposed through an upper surface of the first source line, and
the second memory cell array comprises:
a second source line upper the first memory cell array; and
second source bonding pads included in the second source line and respectively contact the first source bonding pads through a lower surface of the second source line.

21. The memory device of claim 20, wherein the first memory cell array comprises:
a first stack on the first bit lines;
first cell plugs extending through the first stack;
wherein the first source line is on the first cell plugs and the first stack; and
wherein the first source bonding pads are included in the first source line and exposed through an upper surface of the first memory cell array.

22. The memory device of claim 21, wherein the first source bonding pads are formed of a dielectric layer.

23. The memory device of claim 21, further comprising:
a first source contact in the connection region of the first memory cell array and configured to transmit a source voltage generated in the first peripheral circuit to the first source line.

24. The memory device of claim 21, wherein the second memory cell array comprises:
the second source bonding pads contacting the first source bonding pads;
the second source line covering the second source bonding pads;
a second stack over the second source line;
second cell plugs passing through the second stack; and
the second bit lines over the second cell plugs.

25. The memory device of claim 24, wherein the second source bonding pads are formed of the same material as the first source bonding pads.

26. The memory device of claim 24, further comprising:
a second source contact positioned in the connection region the second memory cell array and configured to transmit a source voltage generated in the second peripheral circuit to the second source line.
